(19) United States
(12) Patent Application Publication
(10) Pub. No.: US 2025/0107341 A1
(43) Pub. Date: Mar. 27, 2025

(54) Display Panel and Display Device

(71) Applicant: BOE TECHNOLOGY GROUP CO., LTD., Chaoyang District, Beijing (CN)

(72) Inventors: Wenxiu Zhu, Beijing (CN); Hongli Wang, Beijing (CN)

(21) Appl. No.: 18/727,287

(22) PCT Filed: Jul. 29, 2022
(86) PCT No.: PCT/CN2022/109192

§ 371 Date: Jul. 8, 2024

(51) Int. Cl. H10K 59/122; H10K 59/35

(52) U.S. Cl. CPC H10K 59/122; H10K 59/352; H10K 59/353

(57) ABSTRACT

A display panel includes a base substrate, and a pixel definition layer and pixels that are disposed on the base substrate. The pixel definition layer includes first pixel openings, second pixel openings and third pixel openings. The pixels are arranged in M rows and N columns. A pixel includes a first sub-pixel located at a first pixel opening, a second sub-pixel located at a second pixel opening, and a third sub-pixel located at a third pixel opening. The first sub-pixel, the second sub-pixel and the third sub-pixel emit light of different colors and are sequentially arranged in a third direction. In the third direction, two adjacent sub-pixels that emit light of a same color are separated by at least two sub-pixels that emit light of another colors, and the at least two sub-pixels emit light of colors that are different from each other.

### CROSS-REFERENCE TO RELATED APPLICATION

This application is the United States national phase of International Patent Application No. PCT/CN2022/109192, filed Jul. 29, 2022, the disclosure of which is hereby incorporated by reference in its entirety.

### BACKGROUND OF THE INVENTION

### Field of the Invention

The present disclosure relates to the field of display technologies, and in particular, to a display panel and a display device.

### Description of Related Art

Organic light-emitting diodes (OLEDs) have advantages such as high brightness, full viewing angle, fast response speed, and flexible display. OLED display devices may be classified into passive matrix OLED (PMOLED) and active matrix OLED (AMOLED) according to the driving method. AMOLED display devices have higher luminous efficiency and may be used as high-resolution and large-size display devices.

### SUMMARY OF THE INVENTION

In an aspect, a display panel is provided. The display panel includes a base substrate, a pixel definition layer, and a plurality of pixels. The pixel definition layer is disposed on the base substrate. The pixel definition layer includes a plurality of pixel openings, and the plurality of pixel openings include first pixel openings, second pixel openings, and third pixel openings. The plurality of pixels are arranged on the base substrate, and the plurality of pixels are arranged in M rows and N columns. A row of the M rows include N pixels arranged in a first direction, and a column of the N columns include M pixels arranged in a second direction, where M≥2, and N≥2. The first direction and the second direction intersect. A pixel of the plurality of pixels includes a plurality of sub-pixels emit light of different colors, and the plurality of sub-pixels include a first sub-pixel located at a first pixel opening of the first pixel openings, a second sub-pixel located at a second pixel opening of the second pixel openings, and a third sub-pixel located at a third pixel opening of the third pixel openings; the first sub-pixel, the second sub-pixel and the third sub-pixel are arranged sequentially in a third direction, and the third direction intersects with both the first direction and the second direction.

For all sub-pixels included in the plurality of pixels, in the third direction, two adjacent sub-pixels that emit light of a same color are separated by at least two sub-pixels that emit light of another colors, and the at least two sub-pixels emit light of colors that are different from each other.

In some possible implementations, the display panel further includes a plurality of spacers. The plurality of spacers are located on a side of the pixel definition layer away from the base substrate and located in a region where a portion, except for the plurality of pixel openings, of the pixel definition layer is located.

In some embodiments, the plurality of spacers include a plurality of first spacers. A first spacer of the plurality of first spacers is located between two third pixel openings arranged in the first direction and adjacent to each other and between a first pixel opening and a second pixel opening that are arranged in the second direction and adjacent to each other.

In some possible implementations, at least one of the first pixel opening, the second pixel opening and the third pixel openings that are adjacent to the first spacer is a pixel opening having a chamfered portion. The chamfered portion is located at a position of the pixel opening proximate to the first spacer, and an orthogonal projection of the chamfered portion on the base substrate is non-overlapping with an orthographic projection of the first spacer on the base substrate.

In some possible implementations, the pixel opening having the chamfered portion has a first side wall and a second side wall that are adjacent to the chamfered portion; the chamfered portion and the first side wall form a first vertex angle, and the chamfered portion and the second side wall form a second vertex angle; the first vertex angle is 0.9 times to 1.1 times the second vertex angle.

In some possible implementations, the pixel opening having the chamfered portion further includes a fifth side wall opposite to the second sidewall in the third direction and a sixth side wall opposite to the first side wall in a fourth direction, the fourth direction intersecting with the third direction. A difference between a dimension of the fifth side wall in the fourth direction and a dimension of the second side wall in the fourth direction is a first difference, and a difference between a dimension of the sixth side wall in the third direction and a dimension of the first side wall in the third direction is a second difference; the first difference is equal to the second difference.

In some possible implementations, at least two of the first pixel opening, the second pixel opening and the third pixel openings that are adjacent to the first spacer is a pixel opening having a chamfered portion; a line connecting geometric centers of two adjacent pixel openings in the first direction that each having a chamfered portion and that corresponding to sub-pixels emitting light of a same color of all the sub-pixels is parallel to the first direction.

For example, at least two of the first pixel opening, the second pixel opening and the third pixel openings that are adjacent to the first spacer is a pixel opening having a chamfered portion; a line connecting geometric centers of two adjacent pixel openings in the second direction that each having a chamfered portion and that corresponding to sub-pixels emitting light of a same color of all the sub-pixels is parallel to the second direction.

For example, at least two of the first pixel opening, the second pixel opening and the third pixel openings that are adjacent to the first spacer is a pixel opening having a chamfered portion; a line connecting geometric centers of two adjacent pixel openings in the first direction that each having a chamfered portion and that corresponding to sub-pixels emitting light of a same color of all the sub-pixels is parallel to the first direction; a line connecting geometric centers of two adjacent pixel openings in the second direction that each having a chamfered portion and that corresponding to sub-pixels emitting light of a same color of all the sub-pixels is parallel to the second direction.

In some possible implementations, at least two of the first pixel opening, the second pixel opening and the third pixel openings that are adjacent to the first spacer is a pixel opening having a chamfered portion; in the first direction or the second direction, for two adjacent pixel openings that are each having a chamfered portion and corresponding to sub-pixels emitting light of a same color of all the sub-pixels, a chamfered portion included in each of the two adjacent pixel openings is located at a same corner position of a respective pixel opening of the two adjacent pixel openings.

In some possible implementations, the two adjacent pixel openings have a same shape and a same size.

In some possible implementations, the first sub-pixel, the second sub-pixel and the third sub-pixel in the pixel all extend in a fourth direction, and the fourth direction and the third direction form an included angle in a range of 80° to 100°, inclusive. In some possible implementations, the first pixel opening adjacent to the first spacer is a pixel opening having a chamfered portion, and an orthographic projection of the first spacer on the pixel definition layer and the first pixel opening having the chamfered portion each have a side, and two sides are close to each other and substantially parallel to each other.

For example, the first pixel opening adjacent to the first spacer is a pixel opening having a chamfered portion, and the chamfered portion of the first pixel opening is substantially parallel to the first direction.

For another example, the first pixel opening adjacent to the first spacer is a pixel opening having a chamfered portion, and an orthographic projection of the first spacer on the pixel definition layer and the first pixel opening having the chamfered portion each have a side, and two sides are close to each other and substantially parallel to each other. The first pixel opening adjacent to the first spacer is a pixel opening having a chamfered portion, and the chamfered portion of the first pixel opening is substantially parallel to the first direction.

In some possible implementations, the second pixel opening adjacent to the first spacer is a pixel opening having a chamfered portion; an orthographic projection of the first spacer on the pixel definition layer and the second pixel opening having the chamfered portion each have a side, and two sides are close to each other and substantially parallel to each other.

For example, the second pixel opening adjacent to the first spacer is a pixel opening having a chamfered portion, and the chamfered portion of the second pixel opening is substantially parallel to the first direction.

For another example, the second pixel opening adjacent to the first spacer is a pixel opening having a chamfered portion; an orthographic projection of the first spacer on the pixel definition layer and the second pixel opening having the chamfered portion each have a side, and two sides are close to each other and substantially parallel to each other. The second pixel opening adjacent to the first spacer is a pixel opening having a chamfered portion, and the chamfered portion of the second pixel opening is substantially parallel to the first direction.

In some possible implementations, the third pixel opening adjacent to the first spacer is a pixel opening having a chamfered portion; an orthographic projection of the first spacer on the pixel definition layer and the third pixel opening having the chamfered portion each have a side, and the two sides are close to each other and substantially parallel to each other.

For example, the third pixel opening adjacent to the first spacer is a pixel opening having a chamfered portion, and the chamfered portion of the third pixel opening is substantially parallel to the second direction.

For another example, the third pixel opening adjacent to the first spacer is a pixel opening having a chamfered portion; an orthographic projection of the first spacer on the pixel definition layer and the third pixel opening having the chamfered portion each have a side, and the two sides are close to each other and substantially parallel to each other. The third pixel opening adjacent to the first spacer is a pixel opening having a chamfered portion, and the chamfered portion of the third pixel opening is substantially parallel to the second direction.

In some possible implementations, shapes of orthographic projections of the first spacers on the pixel definition layer include one or more pattern types of a triangle, rectangle, square, parallelogram, trapezoid, hexagon, ellipse and circle.

In some possible implementations, the plurality of pixel openings are divided into a plurality of opening groups arranged in a fourth direction; the fourth direction intersects with the third direction. The plurality of spacers include at least one second spacer; a second spacer is in a shape of a strip and extends in the third direction between two adjacent opening groups of the plurality of opening groups.

In some possible implementations, the two adjacent opening groups include a first opening group and a second opening group, and a length of the first opening group in the third direction is greater than a length of the second opening group in the third direction. A length of the second spacer in the third direction is less than or equal to the length of the first opening group in the third direction and is greater than or equal to the length of the second opening group in the third direction.

In some possible implementations, an orthographic projection of the second spacer on the pixel definition layer and the orthogonal projection of the first opening group on the pixel definition layer each have two ends, and the two ends of one of the orthographic projections of the second spacer and the first opening group are respectively flush with the two ends of another of the orthographic projections of the second spacer and the first opening group.

In some possible implementations, the display panel includes a display area having a contour, and the plurality of spacers are located in the display area. The plurality of spacers include a plurality of third spacers; a third spacer of the plurality of third spacers is located between two adjacent pixel openings that are proximate to the contour of the plurality of pixel openings.

In some possible implementations, an orthographic projection of the third spacer on the pixel definition layer has a side that is proximate to and substantially parallel to the contour.

In some possible implementations, a pixel opening of the two adjacent pixel openings proximate to the contour and an orthographic projection of the third spacer on the pixel definition layer each have a side, and two sides are close to each other and parallel to each other.

In some possible implementations, shapes of orthographic projections of the third spacers on the pixel definition layer include one or more pattern types of a triangle, rectangle, square, parallelogram, trapezoid and ellipse.

In some possible implementations, the plurality of pixel openings are divided into a plurality of opening groups arranged in a fourth direction; the fourth direction intersects with the third direction. The plurality of spacers further include at least one fourth spacer, and a fourth spacer of the at least one fourth spacer is located between an opening group of the plurality of opening groups that is located at outermost of the display panel and the contour.

In some possible implementations, an orthographic projection of the fourth spacer on the pixel definition layer and the opening group located at the outermost of the display panel each have a side, and two sides are close to each other and substantially parallel to each other.

In some possible implementations, an orthographic projection of the fourth spacer on the pixel definition layer has a side that is proximate to and substantially parallel to the contour.

In some possible implementations, in a case where the display panel includes the first spacer and a third spacer, shapes of an orthographic projection of the first spacer and an orthographic projection of the third spacer on the pixel definition layer are different.

For example, in a case where the display panel includes the first spacer and a fourth spacer, the shapes of the orthographic projection of the first spacer and an orthographic projection of the fourth spacer on the pixel definition layer are different.

For another example, in a case where the display panel includes the first spacer, a third spacer and a fourth spacer, shapes of an orthographic projection of the first spacer and an orthographic projection of the third spacer on the pixel definition layer are different, and the shapes of the orthographic projection of the first spacer and an orthographic projection of the fourth spacer on the pixel definition layer are different.

In some possible implementations, in a case where the display panel includes the first spacer and a third spacer, orthographic projections of the first spacer and the third spacer on the pixel definition layer have a same shape and a same size.

In yet another aspect, a display device is provided. The display device includes the display panel as described in any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, accompanying drawings in the following description may be regarded as schematic diagrams, and are not limitations on an actual size of a product, an actual process of a method and an actual timing of signals involved in the embodiments of the present disclosure.

FIG. 1 is a front view of a display device, in accordance with some embodiments;

FIG. 2 is a structural diagram of a display panel, in accordance with some embodiments;

FIG. 3A is a diagram showing a stacked relationship of multiple layers included in the display panel shown in FIG. 2;

FIG. 3B is a structural diagram of an active pattern layer in FIG. 3A;

FIG. 3C is a structural diagram of a first conductive pattern layer in FIG. 3A;

FIG. 3D is a structural diagram of an active pattern layer and a first conductive pattern layer in FIG. 3A;

FIG. 3E is a structural diagram of a third conductive pattern layer in FIG. 3A;

FIG. 3F is a structural diagram of an active pattern layer, a first conductive pattern layer and a third conductive pattern layer in FIG. 3A;

FIG. 3G is an equivalent circuit diagram of a pixel driving circuit R, in accordance with some embodiments;

FIG. 4A is an arrangement diagram of multiple pixel openings in a pixel definition layer shown in FIG. 3A;

FIG. 4B is an arrangement diagram of multiple pixels in a light-emitting device layer shown in FIG. 3A;

FIG. 5 is a structural diagram of a pixel in a light-emitting device layer shown in FIG. 3A;

FIG. 6 is an arrangement diagram of multiple pixels of a light emitting device layer in a comparative example;

FIG. 7A is a schematic diagram of a display panel DP that displays a horizontal line in a comparative example;

FIG. 7B is a schematic diagram of a display panel DP that displays a vertical line in a comparative example;

FIG. 8A is a schematic diagram of a display panel DP that displays a diagonal line in a comparative example;

FIG. 8B is a schematic diagram of a display panel DP that displays another diagonal line in a comparative example;

FIG. 9A is a schematic diagram of a display panel DP that displays a horizontal line, in accordance with some embodiments;

FIG. 9B is a schematic diagram of a display panel DP that displays a vertical line, in accordance with some embodiments;

FIG. 10A is a schematic diagram of a display panel DP that displays a diagonal line, in accordance with some embodiments;

FIG. 10B is a schematic diagram of a display panel DP that displays another diagonal line, in accordance with some embodiments;

FIG. 10C is a diagram showing a connection structure between a sub-pixel and a pixel driving circuit;

FIG. 10D is an alternative structural diagram of FIG. 10C;

FIG. 11A is an alternative structural diagram of FIG. 4A;

FIG. 11B is an alternative structural diagram of FIG. 4B;

FIG. 11C is a perspective view of a second pixel opening in FIG. 11A;

FIG. 11D is a structural diagram of a pixel opening having chamfered portions;

FIG. 12A is a diagram showing an arrangement of spacers and multiple pixel openings;

FIG. 12B is an alternative structural diagram of FIG. 12A;

FIG. 13A is a structural diagram of a pixel opening having a chamfered portion in FIG. 12B;

FIG. 13B is a partial enlarged view of the region H in FIG. 12B;

FIG. 14 is another alternative structural diagram of FIG. 12A;

FIG. 15 is yet another alternative structural diagram of FIG. 12A;

FIG. 16 is yet another alternative structural diagram of FIG. 12A;

FIG. 17 is yet another alternative structural diagram of FIG. 12A;

FIG. 18 is yet another alternative structural diagram of FIG. 12A;

FIG. 19 is yet another alternative structural diagram of FIG. 12A;

FIG. 20 is yet another alternative structural diagram of FIG. 12A;

FIG. 21 is yet another alternative structural diagram of FIG. 12A;

FIG. 22 is diagram showing possible shapes of an orthographic projection of a first spacer on a pixel definition layer;

FIG. 23 is yet another alternative structural diagram of FIG. 12A;

FIG. 24 is yet another alternative structural diagram of FIG. 12A;

FIG. 25 is yet another alternative structural diagram of FIG. 12A; and

FIG. 26 is yet another alternative structural diagram of FIG. 25.

### DESCRIPTION OF THE INVENTION

The technical solutions in embodiments of the present disclosure will be described clearly and completely with reference to the accompanying drawings. Obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, terms such as “first” and “second” are only used for descriptive purposes, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term such as “about”, “substantially” or “approximately” includes a stated value and an average value within an acceptable range of deviation of a particular value, and the acceptable range of deviation is determined by a person of ordinary skill in the art in view of the measurement in question and errors associated with measurement of a particular quantity (i.e., the limitation of the measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the drawings, thicknesses of layers and sizes of regions are enlarged for clarity. Variations in shapes relative to the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

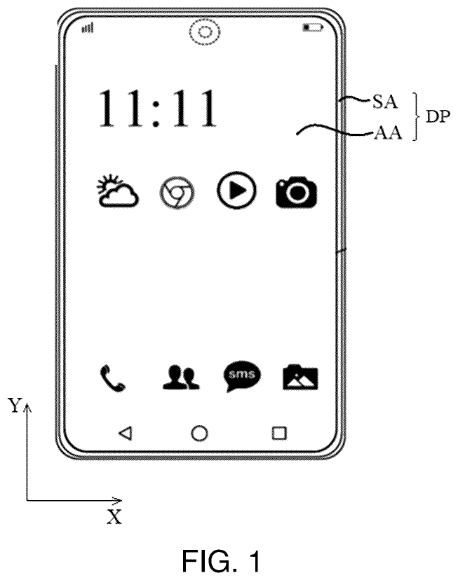

FIG. 1 is a front view of a display device, in accordance with some embodiments. Referring to FIG. 1, some embodiments of the present disclosure provide a display device.

In some implementations, the display devices may be any devices that displays images whether in motion (e.g., videos) or stationary (e.g., still images) and whether text or images. The display devices may include (but are not limited to), for example, displays, televisions, mobile phones (e.g., cellphones), wireless devices, personal digital assistants (PDAs), computers (e.g., hand-held or portable computers), global positioning system (GPS) receivers/navigators, cameras, moving picture experts group 4 (MP4) video players, video cameras, game consoles, watches, clocks, calculators, television monitors, car displays (e.g., odometer displays, cockpit controllers, cockpit displays, or display of rear view camera in vehicles), navigators, electronic photos, electronic billboards or signs, projectors, architectural structures, and packaging and aesthetic structures (e.g., displays for displaying an image of a piece of jewelry).

In some possible implementations, referring to FIG. 1, the display device includes a display panel DP. For example, the display device may further include at least one of a frame, a display driver integrated circuit (DDIC), and a circuit board. The circuit board may be a flexible printed circuit (FPC) or a printed circuit board (PCB).

The circuit board maybe coupled to the DDIC and configured to transmit electrical signals to the DDIC. The DDIC is configured to provide data signals to the display panel DP, for example, configured to generate a data signal based on a received electrical signal, and to send the data signal to the display panel DP. In addition, display panels DP, DDIC and circuit board may be installed into the space enclosed by the frame.

The display panel DP is a screen with a display function, which may be coupled to the DDIC and is configured to receive the data signals sent by the DDIC and display the corresponding image. For example, the display panel DP may be an OLED display panel, a quantum dot light-emitting diode (QLED) display panel, or a tiny light-emitting diode (including a mini LED or a micro LED) display panel.

Referring to FIG. 1, the display panel DP has a display area AA and a non-display area SA; the display area AA is an area of the display panel DP for displaying images, and the non-display area SA is an area of the display panel DP except for the display area AA. The non-display area SA may be located at at least one side (e.g., one side or multiple sides) of the display area AA. For example, the non-display area SA may be disposed around the display area AA.

For example, the display area AA may be in a shape of a rectangle or may be in other shape similar to the rectangle such as a rectangle with rounded corners. Based on this, the display area AA has two sides of which extending direction intersect (e.g., being perpendicular to) each other. For convenience of description, a rectangular coordinate system is established by taking extending directions of the two sides as X-axis and Y-axis, respectively. The X axis and Y axis are interchanged with each other.

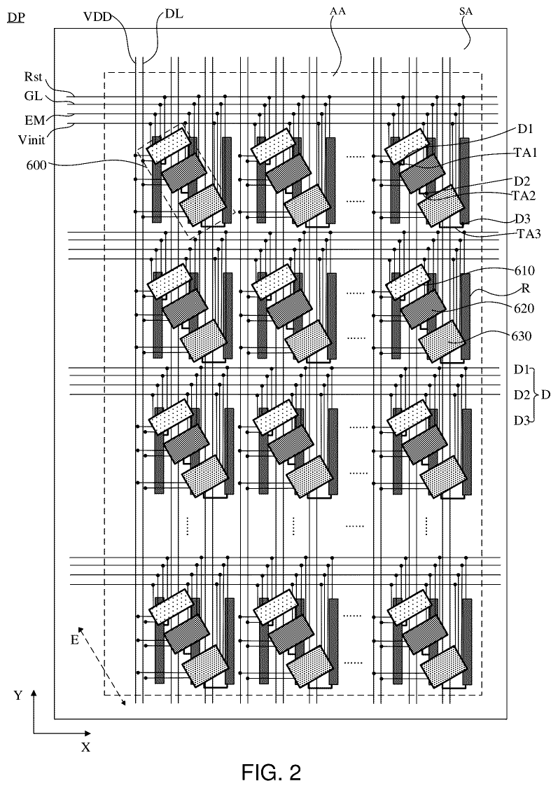

FIG. 2 is a structural diagram of a display panel provided by some embodiments; referring to FIG. 2, a plurality of pixels 600 are provided in the display area AA of the display panel 01. The plurality of pixels 600 are arranged in M rows and N columns, a row include N pixels 600 arranged in a first direction X, and a column includes M pixels 600 arranged in a second direction Y; M≥2, N≥2, and both M and N are integers. The first direction X and the second direction Y intersect, for example, are perpendicular to each other. For example, the first direction X is a direction indicated by the X-axis, so the reference sign of the X-axis is used; the second direction Y is a direction indicated by the Y-axis, so the reference sign of the Y-axis is used. For example, during the display panel DP displays a frame of image, pixels in a same row (including all sub-pixels in the pixels in the same row) may be driven (for example, lit) at the same time, and pixels in different rows are driven in a time-sharing manner. For example, M rows of pixels may be driven row by row. For example, after the first row of pixels is driven, the second row of pixels is driven, and so on, until the Mth row of pixels is driven.

A (e.g., each) pixel 600 includes a plurality of sub-pixels P. A sub-pixel is the smallest unit of the display panel DP for displaying images. Each sub-pixel may display a single color, such as red (R), green (G) or blue (B). The luminance (gray scales) of sub-pixels of different colors in each pixel 600 may be adjusted, and multiple colors may be displayed by color combination and superposition, thereby achieving full-color display of the display panel. For example, the pixel 600 includes a first sub-pixel 610, a second sub-pixel 620, and a third sub-pixel 630. The first sub-pixel 610, the second sub-pixel 620, and the third sub-pixel 630 emit light of different colors and are sequentially arranged in a third direction E. For example, the third sub-pixel 630 may be a blue sub-pixel; one of the first sub-pixel 610 and the second sub-pixel 620 may be a red sub-pixel, and the other may be a green sub-pixel. In some embodiments, the first sub-pixel is a red sub-pixel, and the second sub-pixel is a green sub-pixel. Of course, the colors of light emitted by the first sub-pixel 610 and the second sub-pixel 620 may be interchanged.

Illustratively, a (e.g., each) sub-pixel may include a light-emitting device. The light-emitting device may be, for example, an OLED light-emitting diode, a micro OLED light-emitting diode, a QLED light-emitting diode, a mini light-emitting diode, or a micro light-emitting diode (micro LED). For example, the red sub-pixel includes a light-emitting device for emitting red light, the green sub-pixel includes a light-emitting device for emitting green light, and the blue sub-pixel includes a blue light-emitting device for emitting blue light.

The first sub-pixel 610, the second sub-pixel 620 and the third sub-pixel 630 in a (e.g., each) pixel 600 are sequentially arranged in the third direction E. For example, from the upper left to the lower right of FIG. 2, the first sub-pixel 610, the second sub-pixel 620 and the third sub-pixel 630 of the pixel 600 are arranged in sequence. For another example, from the upper left to the lower right of FIG. 2, the third sub-pixel 630, the second sub-pixel 620 and the first sub-pixel 610 of the pixel 600 are arranged in sequence. The third direction E intersects with both the first direction X and the second direction Y. For example, an angle between the third direction E and the second direction is in a range of 40° to 50°, for example, one of 40°, 42°, 45°, 48° or 50°.

Referring to FIG. 2, the display panel DP further includes a plurality of pixel driving circuits R in the display area AA. Each pixel driving circuit R may be coupled to a sub-pixel (e.g., a light-emitting device) and is configured to drive the sub-pixel to emit light.

The plurality of pixel driving circuits R may be arranged in an array, for example, arranged in M rows and C columns, where C=W×N, where W is a number of sub-pixels included in one pixel. For example, in FIG. 2, one pixel includes three sub-pixels, then W is 3. The number of rows of the pixel driving circuits R and the number of rows of the pixels may be the same, which are both M. The number of columns of the pixel driving circuits R is W times the number of columns of pixels. Each row (i.e., each row of pixel driving circuits R) includes C pixel driving circuits R arranged in the first direction X, and the C pixel driving circuits R are respectively coupled to sub-pixels included in N pixels located in a same row. The pixel driving circuits R located in a same row may be written with the respective data signals at the same time, thereby driving the pixels located in the same row to emit light.

The pixel driving circuit R may include electronic elements such as a plurality of transistors and a capacitor. For example, the pixel driving circuit R may include three transistors and one capacitor, which constitute a 3T1C structure (including a driving transistor, two switching transistors, and one capacitor); alternatively, the pixel driving circuit may include more than three transistors and at least one capacitor, which constitute, for example, a 4T1C structure (i.e., one driving transistor, three switching transistors and one capacitor), a 5T1C structure (i.e., one driving transistor, four switching transistors and one capacitor), or a 7T1C (i.e., one driving transistor, six switching transistors and one capacitor). The transistors may be thin film transistors (TFTs), field effect transistors (e.g., metal oxide semiconductors (MOSs)) or other switching devices with same characteristics.

In some embodiments of the present disclosure, the transistor includes a control electrode, a first electrode and a second electrode; a control electrode of a transistor is a gate of the transistor, a first electrode of the transistor is one of a source and a drain of the transistor, and a second electrode of the transistor is the other of the source and the drain of the transistor. Since the source and the drain of the transistor may be symmetrical in structure, the source may be referred to as a first electrode, and the drain thereof may be referred to as a second electrode.

In some embodiments, as shown in FIG. 2, the display panel DP further includes a plurality of signal lines. These signal lines may be coupled to the plurality of pixel driving circuits R mentioned above and configured to transmit respective electrical signals to each pixel driving circuit R. The plurality of signal lines include one or a combination of a plurality of scanning signal lines GL, a plurality of data lines DL, a plurality of reset signal lines Rst, a plurality of enable signal lines (referred to be as light-emitting control signal lines) EM, a plurality of initialization signal lines Vinit and a plurality of power supply voltage signal lines VDD. Exemplarily, the plurality of scanning signal lines GL, the plurality of enable signal lines EM and the plurality of initialization signal lines Vinit may extend in the first direction X, and the plurality of data lines DL and the plurality of power supply voltage signal lines VDD may extend in the second direction Y. Each pixel driving circuit R may be electrically connected to the scanning signal line GL, the data line DL, the reset signal line Rst, the enable signal line EM, the initialization signal line Vinit and the power supply voltage signal line VDD.

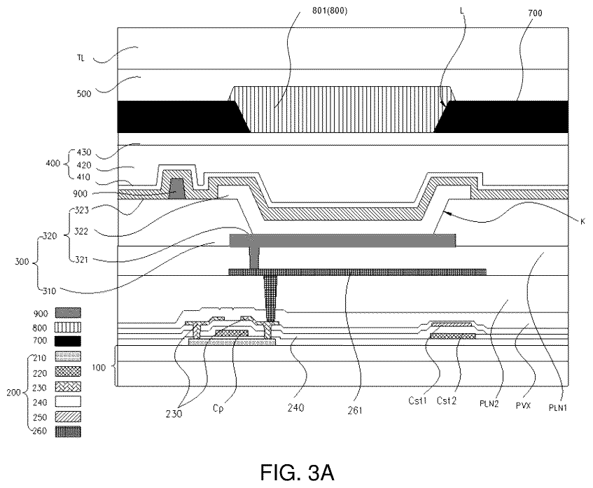

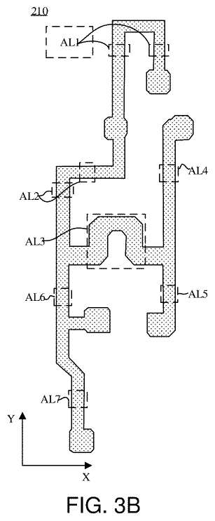

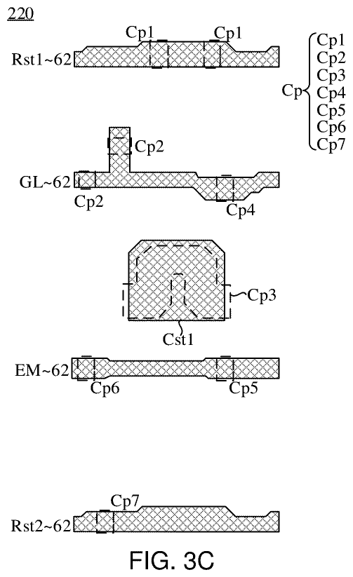

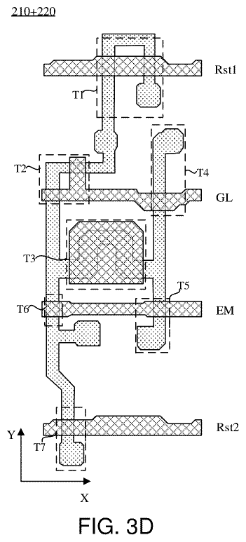

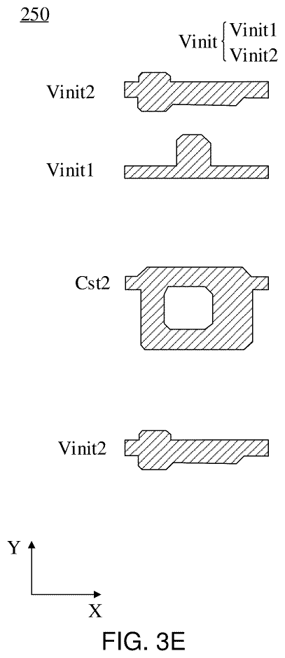

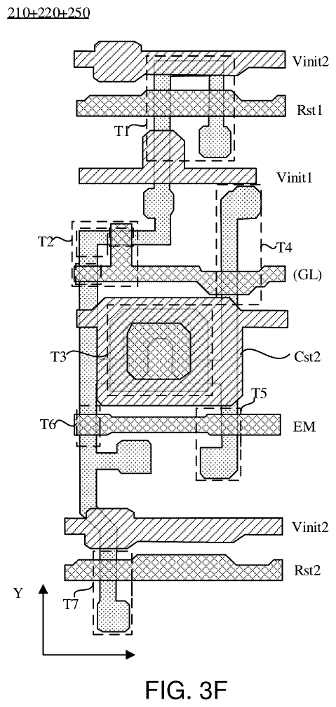

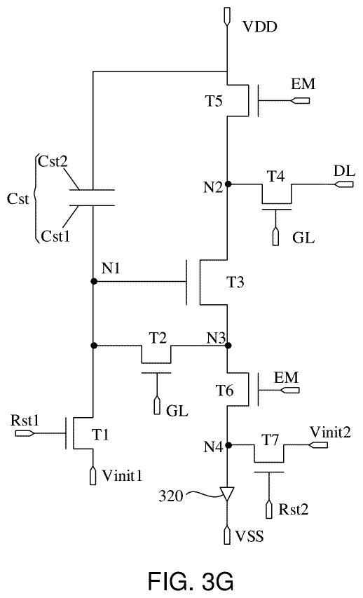

FIG. 3A is a diagram showing a stacked relationship of multiple layers included in the display panel shown in FIG. 2. In order to realize the structure (including the pixels, pixel driving circuits R and signal lines) shown in FIG. 2. For example, referring to FIG. 3A, the display panel DP includes a base substrate 100, a pixel driving circuit layer 200, and a light-emitting device layer 300 that are stacked in sequence. The pixel driving circuit layer 200 includes a plurality of pixel driving circuits R. The light-emitting device layer 300 includes a plurality of light-emitting devices 320 for constituting a plurality of pixels 600.

A structure of the base substrate 100 may be set according to actual needs. The plurality of pixels 600 are disposed on the base substrate 100 (shown in FIG. 3A).

For example, the base substrate 100 is a rigid substrate. The rigid substrate may include, for example, a glass substrate or a polymethyl methacrylate (PMMA) substrate. In this case, the display panel DP may be a rigid display panel.

As another example, the base substrate may be a flexible base substrate. The flexible substrate may include, for example, a polyethylene terephthalate (PET) substrate, a polyethylene naphthalate two formic acid glycol ester (PEN) substrate or a polyimide (PI) substrate. In this case, the display panel 100 may be a flexible display panel.

The base substrate 100 may be of a single-layer structure or a multi-layer structure. For example, the base substrate includes at least one flexible base and at least one buffer layer, and the flexible base and the buffer layer are alternately stacked.

For example, referring to FIG. 3A, the pixel driving circuit layer 200 may include an active pattern layer 210, a first conductive pattern layer 220, and a second conductive pattern layer 230 that are arranged in sequence. The pixel driving circuit layer 200 may further include insulating layers 240 that each separates respective pattern layers. These layers may form the plurality of pixel driving circuits 201.

In the embodiments of the present disclosure, the term “pattern layer” may be of a layer structure that includes specific patterns formed by performing a patterning process on at least one film layer, which is formed by using a same film forming process. Depending on different specific patterns, the patterning process may include several coating, exposure, development or etching processes, and the specific patterns in the formed layer structure may be continuous or discontinuous, and these specific patterns may also be at different heights (or have different thicknesses). The term “conductive pattern layer” is a pattern layer with conductive properties, which is made of a conductive material. For example, the “conductive pattern layer” is made of a transparent conductive material that is selected from, for example, at least one of indium tin oxide (ITO) or aluminum-doped zinc oxide (AZO), which may conduct electricity and have a relatively high light transmittance in a range of visible light. Alternatively, the “conductive pattern layer” may be made of metal materials, for example, may be at least one of aluminum (Al), silver (Ag), copper (Cu), or chromium (Cr).

FIG. 3B is a structural diagram of an active pattern layer in FIG. 3A; referring to FIG. 3B, the active pattern layer 210 may be made of polysilicon (P-Si), and the active pattern layer 210 includes active patterns (which may be referred to as channel regions) of all transistors of the pixel driving circuit R, such as a first active pattern AL1, a second active pattern AL2, a third active pattern AL3, a fourth active pattern AL4, a fifth active pattern AL5, a sixth active pattern AL6 and a seventh active pattern AL7.

Referring to FIG. 3A, the first conductive pattern layer 220 includes a plurality of gate patterns Cp. The second conductive pattern layer 230 includes a plurality of sources and a plurality of drains. A corresponding active pattern, gate pattern Cp, source, and drain may, for example, constitute a transistor, and the plurality of transistors may constitute a pixel driving circuit R.

In addition, the pixel driving circuit layer further includes a third conductive pattern layer 250 located between the first conductive pattern layer 220 and the second conductive pattern layer 230. For example, the first conductive pattern layer 220 further includes a first plate Cst1, and the third conductive pattern layer 250 further includes a second plate Cst2; the first plate Cst1 and the second plate Cst2 are arranged oppositely to form a capacitor Cst in the pixel driving circuit R. In some other examples, the second capacitor plate Cst2 may be included in the second conductive pattern layer 230.

FIG. 3C is a structural diagram of a first conductive pattern layer in FIG. 3A, and FIG. 3D is a structural diagram of an active pattern layer and a first conductive pattern layer in FIG. 3A. Referring to FIGS. 3C and 3D, for example, the first conductive pattern layer 220 and the third conductive pattern layer 250 each include a plurality of signal lines. The first conductive pattern layer 220 includes a plurality of signal lines and the first plate Cst1 of the capacitor. The plurality of signal lines may be, for example, the scanning signal line GL, the reset signal line Rst, and the enable signal line EM. The plurality of signal lines located in the first conductive pattern layer 220 pass through the active patterns of the respective transistors. The positions of the multiple signal lines located in the first conductive pattern layer 220 overlapping with the active patterns of respective transistors are the gate patterns Cp of respective transistors.

For example, referring to FIGS. 3B to 3D, the first reset signal line Rst1 passes through the first active pattern AL1, and the portion of the first reset signal line Rst1 overlapping with the first active pattern AL1 is a first gate pattern Cp1.

The scanning signal line GL passes through the second active pattern AL2 and the fourth active pattern AL4, and the portion of the scanning signal line GL overlapping with the second active pattern AL2 is a second gate pattern Cp2. The portion of the scanning signal line GL overlapping with the fourth active pattern AL4 is a fourth gate pattern Cp4.

The first plate Cst1 passes through the third active pattern AL3, and the portion of the first plate Cst1 overlapping with the third active pattern AL3 is a third gate pattern Cp3.

The enable signal line EM passes through the fifth active pattern AL5 and the sixth active pattern AL6, the portion of the enable signal line EM overlapping with the fifth active pattern AL5 is a fifth gate pattern Cp5, and the portion of the enable signal line EM overlapping with the sixth active pattern AL6 is a sixth gate pattern Cp6.

The second reset signal line Rst2 passes through the seventh active pattern AL7, and the portion of the second reset signal line Rst2 overlapping with the seventh active pattern AL7 is a seventh gate pattern Cp7.

FIG. 3E is a structural diagram of the third conductive pattern layer in FIG. 3A, referring to FIG. 3E, in some embodiments, the third conductive pattern layer 250 includes a plurality of signal lines and a second plate Cst2 of a capacitor. The plurality of signal lines include initialization signal lines Vinit. The initialization signal lines Vinit include first initialization signal lines Vinit1 and second initialization signal lines Vinit2.

It will be noted that “passing through” in the present disclosure means that an orthographic projection of the former on the base overlaps with an orthographic projection of the latter on the base. For example, each signal line in the first conductive pattern layer 220 passes through the active pattern of the respective transistor, which means that an orthographic projection of each signal line (e.g., a scanning signal line GL (not shown in the figure)) in the first conductive pattern layer 220 on the base may overlap with an orthographic projection of the second active pattern AL2 (not shown in the figure) on the base.

The following will be described by taking an example in which the pixel driving circuit R with the 7T1C structure.

FIG. 3F is a structural diagram of the active pattern layer, the first conductive pattern layer and the third conductive pattern layer in FIG. 3A, and FIG. 3G is an equivalent circuit diagram of the pixel driving circuit R in accordance with some embodiments; referring to FIGS. 3F and 3G, for example, the pixel driving circuit R with the 7T1C structure includes a first reset transistor T1, a compensation transistor T2, a driving transistor T3, a writing transistor T4, a first enable transistor T5, a second enable transistor T6, a second reset transistor T7 and a capacitor Cst.

A control electrode of the first reset transistor T1 is electrically connected to the first reset signal line Rst1, a first electrode of the first reset transistor T1 is electrically connected to the first initial signal line Vinit1, and a second electrode of the first reset transistor T1 is electrically connected to a first node N1.

A control electrode of the compensation transistor T2 is electrically connected to the scanning signal line GL, a first electrode of the compensation transistor T2 is electrically connected to a third node N3, and a second electrode of the compensation transistor T2 is electrically connected to the first node N1.

A control electrode of the driving transistor T3 is electrically connected to the first node N1, a first electrode of the driving transistor T3 is electrically connected to a second node N2, and a second electrode of the driving transistor T3 is electrically connected to the third node N3.

A first plate Cst1 of the capacitor Cst is electrically connected to the first node N1, and a second plate Cst2 of the capacitor Cst is electrically connected to a first voltage signal terminal; the first voltage signal terminal is electrically connected to the power supply voltage signal line VDD.

A control electrode of the writing transistor T4 is electrically connected to the scanning signal line GL, a first electrode of the writing transistor T4 is electrically connected to the data line DL, and a second electrode of the writing transistor T4 is electrically connected to the second node N2.

A control electrode of the first enable transistor T5 is electrically connected to the enable signal line EM, a first electrode of the first enable transistor T5 is electrically connected to the power supply voltage signal line VDD, and a second electrode of the first enable transistor T5 is electrically connected to the second node N2.

The control electrode of the second enable transistor T6 is electrically connected to the enable signal line EM. A first terminal of the first capacitor C1 is electrically connected to the third node N3. The second electrode of the second thin film transistor T2 is electrically connected to an anode of a light-emitting device 320 through the third node N3.

A control electrode of the second reset transistor T7 is electrically connected to the second reset signal line Rst2, a first electrode of the second reset transistor T7 is electrically connected to the second initialization signal line Vinit2, and a second electrode of the second reset transistor T7 is electrically connected to a connection node N4 between the second electrode of the second enable transistor T6 and an anode of a light-emitting device 320; a cathode of the light-emitting device 320 is electrically connected to the second voltage signal line VSS. The second voltage signal line VSS transmits a low-level signal; for example, a voltage of the low-level signal is zero.

The specific operation process of each of the above transistors is as follows. In a data writing period, the compensation transistor T2 and the writing transistor T4 are turned on under the control of a scanning signal received from the scanning signal line GL, and write a data signal received from the data signal line DL into the first node N1, and compensate the threshold voltage of the driving transistor T3. In a case where the driving transistor T3 is turned off, the voltage of the first node N1 is a sum of the data signal and the threshold voltage of the driving transistor T3, and the voltage of the first node N1 may control the magnitude of the driving current through the driving transistor T3.

In a light-emitting period, the compensation transistor T2 and the writing transistor T4 are turned off under the control of the scanning signal, and the first enable transistor T5 and the second enable transistor T6 are turned on under the control of an enable signal received from the enable signal line EM, the driving transistor T3 is turned on and generates the driving current, and transmits the driving current to the light-emitting device 320. The light-emitting device 320 emits light under the control of the driving current. The magnitude of the driving current affects the luminance of the light, that is, the voltage of the first node N1 may control the luminance of the light-emitting device 320, i.e., control the gray scale of the sub-pixel, thereby affecting the quality of the entire display image.

It will be noted that the first node N1, the second node N2 and the third node N3 in the embodiments of the present disclosure do not represent actual existing components, but represent junctions of relevant circuit connections in the layout of the pixel driving circuit R; that is, the first node N1, the second node N2 and the third node N3 are nodes that are equivalent to the junctions of electrical connections of relevant lines in the circuit diagram.

Referring to FIG. 3A, the light-emitting device layer 300 may include a pixel definition layer 310 and a plurality of light-emitting devices 320. The pixel definition layer 310 has a plurality of pixel opening K, and a pixel opening defines a region of a light-emitting device 320.

For example, the light-emitting device 320 includes a first electrode (e.g., an anode) 321, a light-emitting layer 322, and a second electrode (e.g., a cathode) 323 that are stacked in sequence.

For example, a structure of the first electrode 321 may be of a composite structure composed of a transparent conductive oxide film/a metal film/a transparent conductive oxide film that are stacked in sequence. The material of the transparent conductive oxide film is, for example, any one of indium tin oxide (ITO) and indium zinc oxide (IZO), and the material of the metal film is, for example, any one of gold (Au), silver (Ag), nickel (Ni) and platinum (Pt).

For another example, the structure of the first electrode 321 may be of a single-layer structure, and the material of the single-layer structure may be any one of ITO, IZO, Au, Ag, Ni, and Pt.

Referring to FIG. 3A, for example, for the plurality of pixel openings K in the pixel definition layer 310, a pixel opening K exposes a portion of a first electrode 321, and at least a portion of a light-emitting layer 322 is located in a pixel opening K and is electrically connected to the corresponding first electrode 321. That is, each light-emitting layer 322 is electrically connected to the corresponding first electrode 321 through a portion of the light-emitting layer 322 that is located in the corresponding pixel opening K or the entirety light-emitting layer 322.

Here, the arrangement manner of the light-emitting layer 322 is related to the manufacturing process of the light-emitting layer 322. For example, in a case where the light-emitting layer 322 is formed by using an evaporation process, a portion of the light-emitting layer 322 may be located in the corresponding pixel opening K, and the other portion is lapped on the pixel definition layer 310 around the pixel opening K. Of course, the entire light-emitting layer 322 may be located in the corresponding pixel opening K. In a case where the light-emitting layer 322 is formed by inkjet printing, the entire light-emitting layer 322 may be located in the corresponding pixel opening K.

Referring to FIG. 3A, for example, the second electrode 323 is located on a side of the pixel definition layer 310 away from the base substrate 100. The second electrodes 323 of the light-emitting devices 60 are connected to one another to form a one-piece structure.

For example, the material of the second electrode 323 may be any one of aluminum (Al), Ag, and magnesium (Mg), or any one of magnesium-silver alloy and aluminum-lithium alloy.

Of course, the light-emitting device 300 may further include at least one of a hole injection layer, a hole transport layer and an electron blocking layer that are disposed between the first electrode 321 and the light-emitting layer 322, and at least one of an electron injection layer, an electron transport layer and a hole blocking layer that are disposed between the second electrode 323 and the light-emitting layer 322.

Referring to FIG. 3A, in some possible implementations, the display panel DP may further include a first planarization layer PLN1 located between the light-emitting device layer 300 and the pixel driving circuit layer 200, and the first planarization layer PLN1 is in direct contact with the light-emitting device layer 300.

Referring to FIG. 3A, in a case where the display panel DP further includes the first planarization layer PLN1, the first electrode 321 of the light-emitting device 320 is disposed on a surface of the first planarization layer PLN1 away from the base substrate 100. A first electrode 321 of a light-emitting device layer 300 may be electrically connected to a pixel driving circuit R penetrating through the first planarization layer PLN1.

Referring to FIG. 3A, in some possible implementations, the display panel DP may further include a fourth conductive pattern layer 260 located between the first planarization layer PLN1 and the pixel driving circuit layer 200. The fourth conductive pattern layer 260 includes a plurality of connecting portions 261.

In a case where the pixel driving circuit layer 200 further includes the fourth conductive pattern layer 260, a first electrode 321 of a light-emitting device 320 may be electrically connected to a pixel driving circuit R through a connecting portion 261.

Referring to FIG. 3A, in some possible implementations, the display panel DP may further include a second planarization layer PLN2 and a passivation layer PVX that are located on a side of the pixel driving circuit layer 200 away from the base substrate 100. The second planarization layer PLN2 may be made of an organic insulating material. The passivation layer PVX may be made of an inorganic insulating material.

Referring to FIG. 3A, in some possible implementations, the display panel DP further includes an encapsulation layer 400 disposed on a side of the light-emitting device layer 300 away from the base substrate 100.

Referring to FIG. 3A, for example, the encapsulation layer 400 includes a first inorganic encapsulation layer 410, an organic encapsulation layer 420 and a second inorganic encapsulation layer 430 that are sequentially stacked.

For example, the first inorganic insulating layer 410 and the second inorganic insulating layer 430 may be made of inorganic materials of nitride, oxide, oxynitride, nitrate, carbide or any combination thereof. The organic insulation layer 420 may be made of acrylon, hexamethyldisiloxane, polyacrylates, polycarbonates, polystyrenes and other materials.

Referring to FIG. 3A, in some possible implementations, the display panel DP further includes a light shielding layer 700 and a filter pattern layer 800 that are disposed on the side of the pixel definition layer 310 away from the base substrate 100. The light shielding layer 700 is provided with a plurality of filter openings L therein. The filter pattern layer 800 includes a plurality of filter patterns 810. A filter opening L corresponds to a filter pattern 810, that is, the filter opening L and the filter pattern 810 have an overlapping portion in a thickness direction of the display panel DP. The filter opening L is used to define the position of the filter pattern 810.

Referring to FIG. 3A, in some possible implementations, the display panel DP further includes a touch layer TL. Thus, the display panel DP is a touch display panel, which is a product having a touch function and an image display function. With continued reference to FIG. 3A, the touch layer TL is configured to provide touch signals, and the touch signals may reflect the touch position of the user on the display panel DP. The touch layer TL may be coupled to a touch chip to provide the touch signals to the touch chip.

In some possible implementations, the touch layer TL may be located on a display side of the display panel DP. The touch layer TL may be a component independent of the display panel DP. For example, the display panel DP and the touch layer TL are formed separately and then bonded together by an adhesive such as an optical adhesive. For example, the encapsulation layer 400 described above may serve as a display surface of the display panel DP. The touch layer TL may be formed on the encapsulation layer 400 by photolithography or other processes. For another example, the touch layer TL may be of a structure integrated on the display panel DP. For example, the display panel DP is used as a substrate, the touch layer TL is formed on the display surface of the display panel DP. In this case, the touch layer TL is in direct contact with the display surface of the display panel DP, or other functional layers are provided between the touch layer TL and the display surface of the display panel DP.

In some other possible implementations, the touch layer may be located inside the display panel. For example, the display panel includes a first substrate and a second substrate that are disposed oppositely, and the touch layer may be located between the first substrate and the second substrate.

Referring to FIGS. 3A, in some possible implementations, the display panel DP further includes a buffer layer 500. The buffer layer 500 is disposed on a side of the light shielding layer 700 away from the base substrate 100. The touch layer TL is disposed on the buffer layer 500 and may be in contact with the buffer layer 500. The buffer layer 500 may be made of an organic insulating material or inorganic insulating material.

The light-emitting device layer in FIG. 3A will be described in detail below.

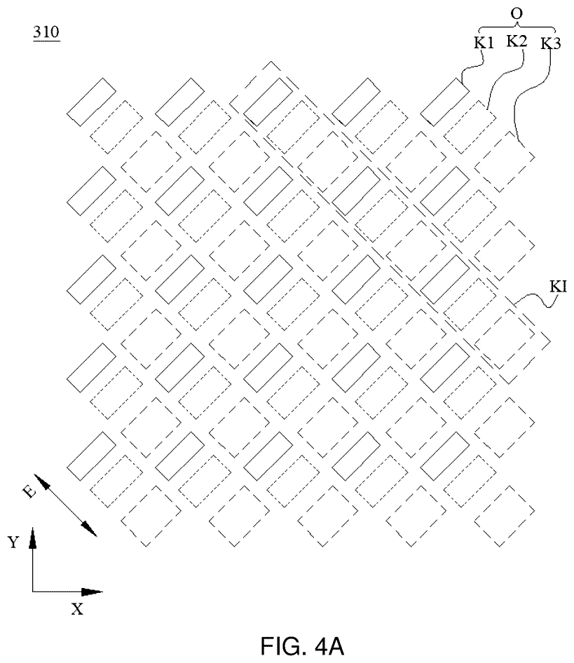

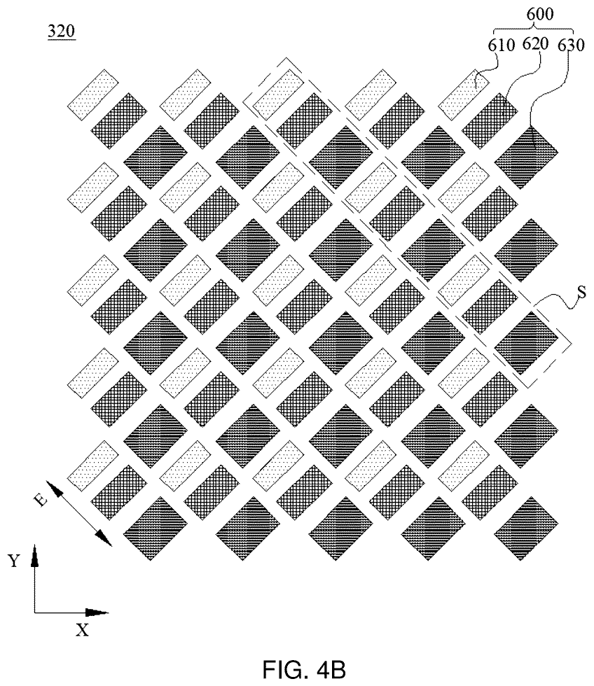

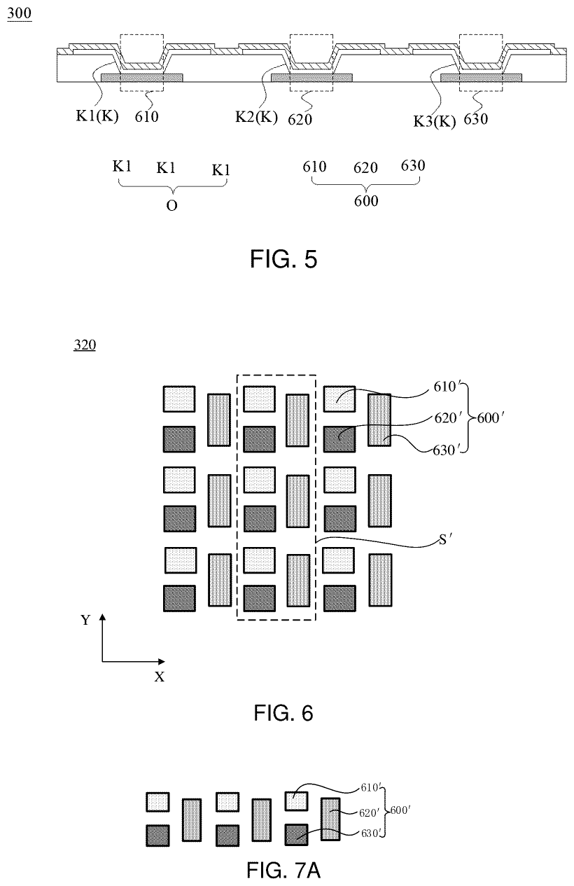

FIG. 4A is an arrangement diagram of multiple pixel openings in the pixel definition layer shown in FIG. 3A, and FIG. 4A shows a lower end of each pixel opening K. FIG. 4B is an arrangement diagram of multiple pixels in the light-emitting device layer shown in FIG. 3A, and FIG. 4B shows a light-emitting region of each sub-pixel in the pixel. FIG. 5 is a structural diagram of a pixel in the light-emitting device layer shown in FIG. 3A.

Referring to FIGS. 4A to 5, in the display panel DP described above, the plurality of pixel openings K in the pixel definition layer 310 include a plurality of first pixel openings K1, a plurality of second pixel openings K2, and a plurality of third pixel openings K3. Based on a case that a pixel opening K corresponds to a position of a sub-pixel, a group of pixel openings corresponding to the position of a pixel 600 is referred to be as an opening unit O herein. The pixel 600 includes a plurality of sub-pixels that emitting light of different colors. The plurality of sub-pixels include a first sub-pixel 610 located at the first pixel opening K1, a second sub-pixel 620 located at the second pixel opening K2 and a third sub-pixel 630 at the third pixel opening K3. The first sub-pixel 610, the second sub-pixel 620 and the third sub-pixel 630 are arranged in sequence in the third direction E. Correspondingly, the opening unit O includes a first pixel opening K1, a second pixel opening K2 and a third pixel opening K3 sequentially arranged in the third direction E.

In the third direction E, two sub-pixels emitting a same color and adjacent in position are separated by at least two sub-pixels emitting other colors, and the at least two sub-pixels emit light of colors that are different from each other. For example, in the third direction E, two adjacent first sub-pixels 610 are separated by a second sub-pixel 620 and a third sub-pixel 630. For another example, in the third direction E, two adjacent second sub-pixels 620 are separated by a third sub-pixel 630 and a first sub-pixel 610. Two adjacent third sub-pixels 630 are separated by a first sub-pixel 610 and a second sub-pixel 620. In this way, each pixel 600 includes a first sub-pixel 610, a second sub-pixel 620 and a third sub-pixel 630.

Referring to FIG. 4A, the plurality of pixel openings K may be divided into a plurality of opening groups KI, and all pixel openings K in each opening group KI are arranged in the third direction E. Illustratively, each opening group KI is composed of an integer number (i.e., at least one, such as one or more) of opening units O. In a case where an opening group KI includes multiple opening units O, these opening units O are arranged in a row in the third direction E.

For example, in the opening units O located in a same row (all opening units corresponding to the pixels in a same row), the pixel openings K of a same type are also located in a same row; for example, first pixel openings K1 are arranged in the first direction X; similarly, the second pixel openings K2 are also arranged in the first direction X; and the third pixel openings K3 are also arranged in the first direction X. For another example, in the opening units O located in a same column, the pixel openings K of a same type are also located in a same column; for example, the first pixel openings K1 are arranged in the second direction Y; similarly, the second pixel openings K2 are also arranged in the second direction Y, and the third pixel openings K3 are also arranged in the second direction Y.

Referring to FIG. 4A, some embodiments of the present disclosure provide a display panel DP. In the display panel DP, an area of the first pixel opening K1 is less than an area of the second pixel opening K2, which means that an area of an orthogonal projection of the first pixel opening K1 on the base substrate 100 is less than an area of an orthogonal projection of the second pixel opening K2 on the base substrate 100. In addition, the area of the second pixel opening K2 is less than an area of the third pixel opening K3, which means that the area of the orthogonal projection of the second pixel opening K2 on the base substrate 100 is less than an area of an orthogonal projection of the third pixel opening K3 on the base substrate 100. Correspondingly, an area of an opening region of the first sub-pixel 610 is less than an area of an opening region of the second sub-pixel 620. The area of the opening area of the second sub-pixel 620 is less than an area of an opening region of the third sub-pixel 630.

Referring to FIG. 4B, the plurality of sub-pixels may be divided into a plurality of sub-pixel groups S, and all sub-pixels in each sub-pixel group S are arranged in the third direction E. Illustratively, each sub-pixel group S is composed of an integer number (i.e., at least one, such as one or more) pixels 600. In a case where a sub-pixel group S includes multiple pixels 600, these pixels 600 are arranged in a row in the third direction E.

FIG. 6 is an arrangement diagram of multiple pixels of a light-emitting device layer in a comparative example. Referring to FIG. 6, in a comparative example, a plurality of pixels 600′ of the display panel DP (not shown in the figure) are arranged into M rows and N columns in the first direction X and the second direction Y, each column includes multiple pixels 600′ are arranged in the second direction Y, and one (e.g., each) pixel 600′ includes a red sub-pixel 610′, a green sub-pixel 620′ and a blue sub-pixel 630′. The red sub-pixels 610′ and the green sub-pixels 620′ are arranged sequentially in the second direction Y, and the blue sub-pixels 630′ are arranged on a side (e.g., a side indicated by the first direction X) of the red sub-pixels 610′ and the green sub-pixels 620′. The extending direction of the sub-pixel group S′ is consistent with the second direction Y. Under the premise that an area of a blue sub-pixel 630′ in a pixel 600′ is constant, if the blue sub-pixel 630′ is made elongated (for example, a dimension of the blue sub-pixel 630′ in the second direction Y is a length, and a dimension of the blue sub-pixel 630′ in the first direction X is a width; in a case where the blue sub-pixel 630′ is made elongated, a ratio of the length to the width is great), the display effect is affected. Therefore, the ratio of the length to the width of the blue sub-pixel 630′ needs to be made small. However, in this case, a spacing between the blue sub-pixels 630′ in the second direction Y is increased, causing a fact that the space of the spacing is unused, and in turn resulting in a reduction of pixels per inch (PPI).

Referring to FIGS. 4A and 4B, in this embodiment, the first sub-pixel 610, the second sub-pixel 620 and the third sub-pixel 630 of the pixel 600 are arranged in sequence in the third direction E. Multiple pixels arranged in the third direction E are grouped into a sub-pixel group S. In this way, the spacing between two adjacent sub-pixels in the sub-pixel group S may be configured as needed. For example, the spacing between the first sub-pixel 610 and the second sub-pixel 620 is substantially equal to the spacing between the second sub-pixel 620 and the third sub-pixel 630. The spacing between any two adjacent sub-pixels is equal or substantially equal. It can be seen that in this embodiment, the problem of excessive spacing between two adjacent sub-pixels will not occur, so that the space may be fully utilized for the arrangement of the sub-pixels, thereby improving the PPI.

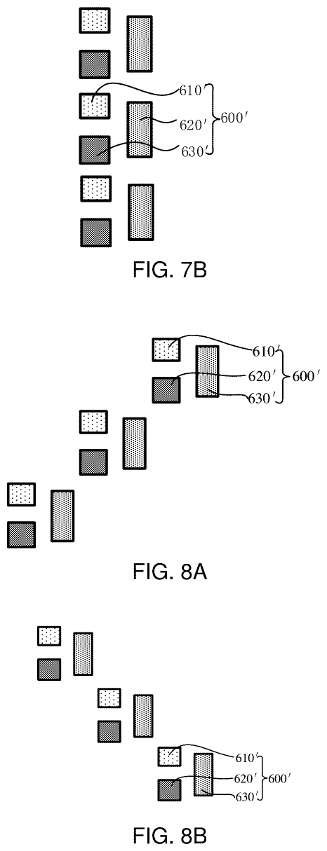

FIG. 7A is a schematic diagram of the display panel DP that displays a horizontal line in the comparative example. Referring to FIG. 7A, in the above comparative example, when the display panel DP needs to display a horizontal line, at least one row (one row or multiple consecutive rows) of pixels corresponding to the horizontal line is lit by the pixel driving circuits R in the row. Among the multiple pixels 600 in these rows, there are first sub-pixels 610 (e.g., red sub-pixels) and third sub-pixels 630 (e.g., blue sub-pixels) proximate to the upper edge of the displayed horizontal line. However, the human eyes are not sensitive to the recognition of blue (third sub-pixels 630), and the third sub-pixel 630 is farther from the upper edge than the first sub-pixel 610, so that the upper edge of the displayed horizontal line will be reddish. There are a second sub-pixel 620 (e.g., green sub-pixels) and third sub-pixels 630 (e.g., blue sub-pixels) proximate to the lower edge of the displayed horizontal line. However, the human eyes are not sensitive to the recognition of blue (third sub-pixels 630), and the third sub-pixel 630 is farther away from the lower edge than the green sub-pixel 620′, so that the lower edge of the displayed horizontal line will be greenish.

FIG. 7B is a schematic diagram of the display panel DP that displays a vertical line in the comparative example. Referring to FIGS. 7A and 7B, in the above comparative example, since the human eye has poor ability to recognize blue (e.g., the color of light emitted by the blue sub-pixel 630′), the human eyes can see red (e.g., the color of light emitted by the red sub-pixel 610′) and green (e.g., the color of light emitted by the green sub-pixel 620′). In this way, when horizontal and vertical lines are displayed, the vertical line is thinner and the horizontal line is thicker.

FIG. 8A is a schematic diagram of the display panel DP that displays a diagonal line in the comparative example, and FIG. 8B is a schematic diagram of the display panel DP that displays another diagonal line in the comparative example. Referring to FIGS. 8A and 8B, in addition, in the above comparative example, when the display panel DP displays a diagonal line, the displayed diagonal line is composed of dots, each dot is displayed and emitted by a pixel, and the arrangement of the pixels in this comparative example the example causes a step between two adjacent pixels, so that a step-like shape will occur when the diagonal line is displayed in the comparison example.

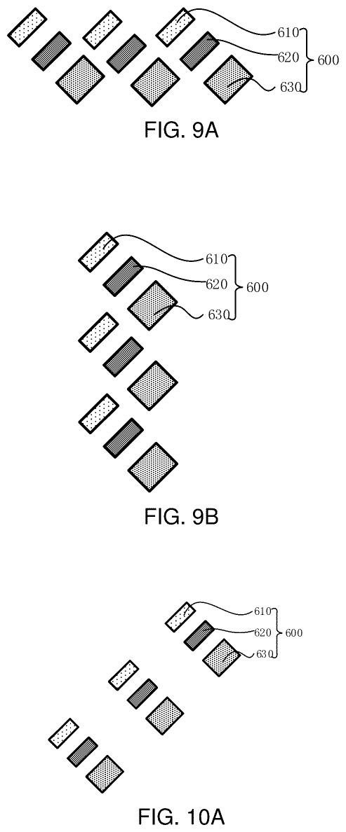

FIG. 9A is a schematic diagram of the display panel DP that displays a horizontal line in accordance with some embodiments. Referring to FIG. 9A, in this embodiment, when the display panel DP displays a horizontal line, among the multiple pixels 600 in a row, in addition to the first sub-pixels 610 (e.g., red sub-pixels), there are second sub-pixels 620 (e.g., green sub-pixels) slightly farther from the upper edge than the first sub-pixels 610 at the upper edge of the horizontal line. Moreover, human eyes are more sensitive to red and green. Therefore, when the horizontal line is displayed, both the first sub-pixels 610 and the second sub-pixels 620 can be seen at the upper edge of the displayed horizontal line. Thus, there will be no color cast of reddish or greenish at the upper edge of the displayed horizontal line. In addition, among the multiple pixels 600 in a row, in addition to the third sub-pixels 630 (e.g., the blue sub-pixels) there are also second sub-pixels 620 (e.g., green sub-pixels) slightly farther from the lower edge than the third sub-pixels 630 at the lower edge of the display horizontal line. Moreover, human eyes are not sensitive to blue, and the second sub-pixels 620 are slightly farther from the lower edge. Therefore, when the horizontal line is displayed, both the third sub-pixels 630 and the second sub-pixels 620 can be seen at the lower edge of the displayed horizontal line. Thus, there will be no color cast of reddish or greenish at the lower edge of the displayed horizontal line.

FIG. 9B is a schematic diagram of the display panel DP that displays a vertical line in accordance with some embodiments. Referring to FIGS. 9A and 9B, in this embodiment, when the display panel DP displays a vertical line, the human eyes are not sensitive to blue, but can see red and green. Therefore, when a horizontal line and a vertical line are displayed, the width of the two is the same.

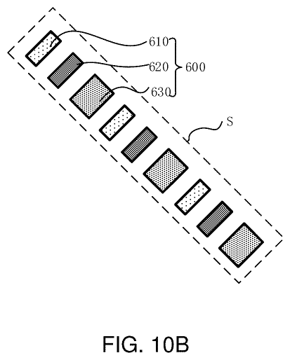

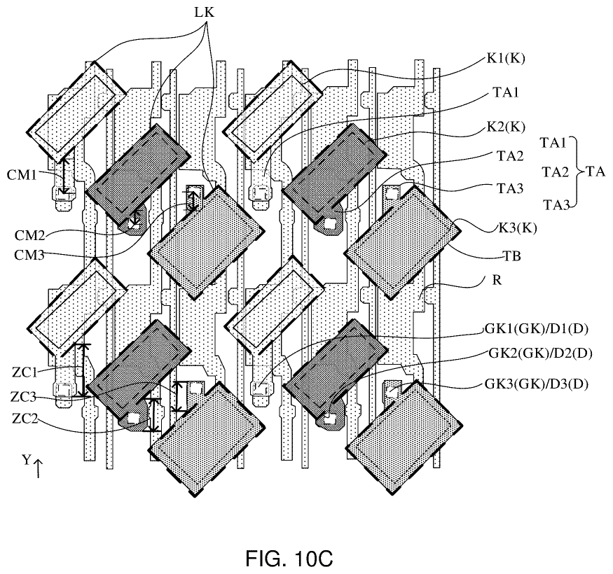

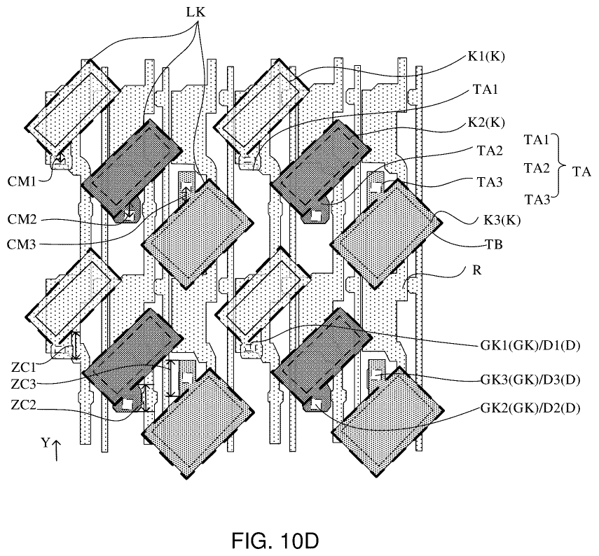

FIG. 10A is a schematic diagram of the display panel DP that displays a diagonal line in accordance with some embodiments, and FIG. 10B is a schematic diagram of the display panel DP that displays another diagonal line in accordance with some embodiments. Referring to FIGS. 10A and 10B, in these embodiments, when the display panel DP displays a diagonal shape, the first sub-pixel 610, the second sub-pixel 620 and the third sub-pixel 630 of each of the multiple pixels 600 in a sub-pixel group S are all arranged in a display direction of the diagonal line; furthermore, the first sub-pixel 610, the second sub-pixel 620 and the third sub-pixel 630 have no overlapping portions in the display direction of the diagonal line. Therefore, when the display panel DP displays a diagonal line shape, the pixels 600 are continuous, so that the displayed diagonal line does not have a step-like shape.

It can be seen that due to the arrangement of the pixels 600 in these embodiments, the area of the third sub-pixel 630 may be increased, thereby achieving the effect of increasing the aperture ratio of the third sub-pixel 630. In addition, when the display panel DP displays a horizontal line, there will be no color cast of reddish or greenish at the edges of the displayed horizontal line. Moreover, when the display panel DP displays a diagonal line, the pixels 600 are continuous, so that the displayed diagonal line does not have a step-like shape.

FIG. 10C is a diagram showing a connection structure between a sub-pixel and a pixel driving circuit, and FIG. 10D is an alternative structural diagram of FIG. 10C. Referring to FIGS. 2 and 3A and FIGS. 10C to FIG. 10D, in some possible implementations, each sub-pixel has a coupling point D coupled to the pixel driving circuit R. The sub-pixel includes a first electrode (e.g., an anode) 321 and a second electrode (e.g., a cathode) 323 that are oppositely arranged. The first electrode 321 is located on a side of the sub-pixel proximate to the base substrate 100. The first electrode 321 of the sub-pixel has an overlapping portion overlapping with the corresponding pixel driving circuit R, and the overlapping portion is provided with a via hole GK therein (a via hole of the first sub-pixel 610 is represented as GK1, a via hole of the second sub-pixel 620 is represented as GK2, and a via hole of the third sub-pixel 630 is represented as GK3). The first electrode 321 of the sub-pixel is electrically connected to the pixel driving circuit R at the position of the via hole GK. The coupling point D refers to the position where the via hole GK is located.

In the second direction Y, a distance between a geometric center (which may be referred to as a geometric center of gravity) of the coupling point D of each of at least two sub-pixels that emitting light of different colors and the respective pixel opening K is different. The distance between the coupling point D and the pixel opening K refers to a distance, in the second direction Y, from the geometric center of the coupling point D to a point on the pixel opening K that is closest to the coupling point D. To facilitate the following description, the coupling point of the first sub-pixel 610 is represented as D1, the coupling point of the second sub-pixel 620 is represented as D2, and the coupling point of the third sub-pixel 630 is represented as D3. In the second direction Y, the distance between the coupling point D1 and the first pixel opening K1 is represented as CM1, the distance between the coupling point D2 and the second pixel opening K2 is represented as CM2, and the distance between the coupling point D3 and the third pixel opening K3 is represented as CM3. The distance between each of at least two of the three of the coupling points D1, D2 and D3 and the respective pixel opening (e.g., the first pixel opening K1, the second pixel opening K2, or the third pixel opening K3) is different. For example, the coupling points D1, D2 and D3 each have a different distance from the respective pixel opening K. As another example, as shown in FIG. 10C, the distance CM1 is greater than both the distances CM2 and CM3, and the distance CM2 is substantially equal to the distance CM3. As another example, as shown in FIG. 10D, the distance CM3 is greater than both the distances CM1 and CM2, and the distance CM1 is substantially equal to the distance CM2.

Referring to FIGS. 2 and 3A and FIGS. 10C to 10D, in some possible implementations, the first electrode 321 includes a connecting portion TA and a main body portion TB that are connected to be one-piece structure. The pixel opening K exposes at least a portion of the main body portion TB. For example, an orthographic projection of a portion of the main body portion TB the base substrate 100 overlaps with an orthogonal projection of the pixel opening K on the base substrate 100, and an orthographic projection of the other portion of the main body portion TB does not overlap with the orthogonal projection of the pixel opening K on the base substrate 100. For another example, an orthographic projection of the main body portion TB on the base substrate is located within the orthogonal projection of the pixel opening K on the base substrate 100. The coupling point D of the sub-pixel is located in a region where the connecting portion TA is located. The main body portion TB has a same shape as the corresponding pixel opening K, and an outline LK of the main body portion TB expands outward by one circle from the pixel opening K corresponding to the main body portion TB. The outline LK of the main body portion TB serves as a dividing line between the connecting portion TA and the main body portion TB.

Two connecting portions TA corresponding to at least two sub-pixels that emitting light of different colors (e.g., two or three of the first sub-pixel 610, the second sub-pixel 620 and the third sub-pixel 630 that emitting light of different colors) each have a different maximum dimension in the second direction Y. For ease of description below, the connecting portion corresponding to the first sub-pixel 610 is referred to as a first connecting portion TA1, the connecting portion corresponding to the second sub-pixel 620 is referred to as a second connecting portion TA2, and the connection portion corresponding to the third sub-pixel 630 is referred to as a third connecting portion TA3. The maximum dimension of the first connecting portion TA1 in the second direction Y is referred to as a first maximum dimension ZC1, the maximum dimension of the second connecting portion TA2 in the second direction Y is referred to as a second connecting portion TA2, and the maximum dimension of the third connecting portion TA3 in the second direction Y is referred to as a third maximum dimension ZC3. For example, as shown in FIG. 10C, the first maximum dimension ZC1 is greater than the second maximum dimension ZC2 and the third maximum dimension ZC3. The second maximum dimension ZC2 is substantially the same as the third maximum dimension ZC3. As another example, as shown in FIG. 10D, the third maximum dimension ZC3 is greater than the second maximum dimension ZC2 and the first maximum dimension ZC1. The second maximum dimension ZC2 is substantially the same as the first maximum dimension ZC1.

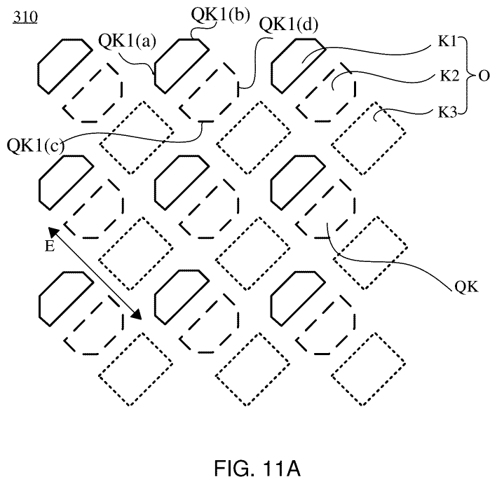

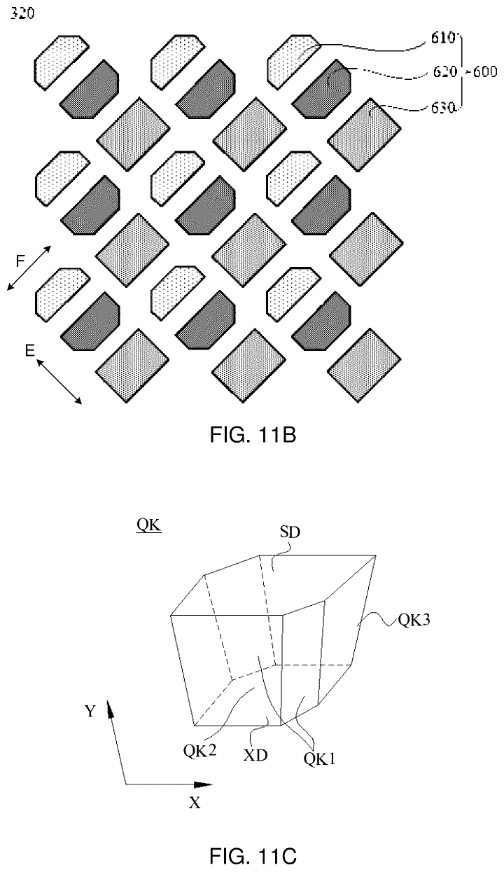

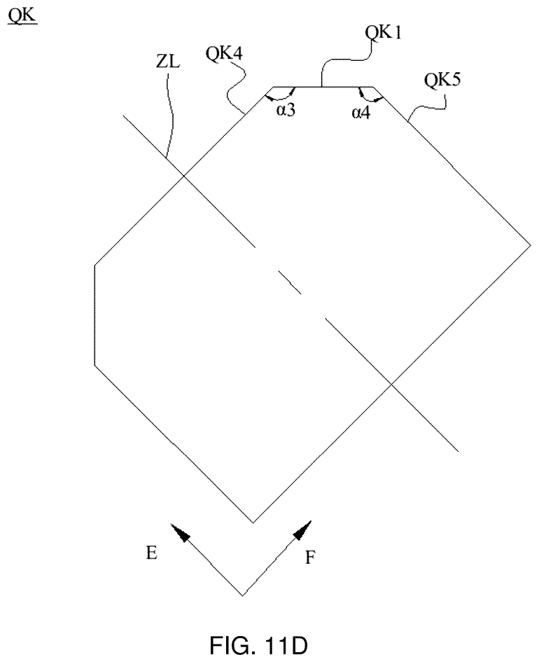

FIG. 11A is an alternative structural diagram of FIG. 4A, and FIG. 11B is an alternative structural diagram of FIG. 4B. Referring to FIG. 11A, some embodiments of the present disclosure provide a display panel DP. In the display panel DP, at least one of the first pixel opening K1, the second pixel opening K2 and the third pixel opening K3 included in the opening unit O is a pixel opening having a chamfered portion. For convenience of description below, the pixel opening having the chamfered portion is referred to as a chamfered opening QK. For example, an opening unit O includes a first pixel opening K1, a second pixel opening K2, and a third pixel opening K3, and any one or two of the three are chamfered openings QK, and the remaining pixel openings are not chamfered openings QK; alternatively, all the three are chamfered openings QK.

For example, FIG. 11C is a perspective view of the second pixel opening in FIG. 11A. Referring to FIG. 11C, the chamfered opening QK has a chamfered portion QK1. For example, the lower end XD of the chamfered opening QK is substantially in a shape of a polygon; for the chamfered portion QK1 of the chamfered opening QK, at least one (e.g., one or more) corner of the polygon is recessed. For example, the lower end of the chamfered opening QK is substantially in a shape of rectangle of which two corners are recessed. The lower end XD of the chamfered opening QK refers to a portion of the lower surface, for exposing the first electrode 321, of the pixel opening K (e.g., the first pixel opening K1, the second pixel opening K2, or the third pixel opening K3). The upper end SD of the chamfered opening QK refers to a portion corresponding to the upper surface of the pixel opening K (e.g., the first pixel opening K1, the second pixel opening K2, or the third pixel opening K3). Correspondingly, the shape of the upper end SD of the chamfered opening QK is substantially the same as that of the lower end XD of the chamfered opening QK, and for the chamfered portion QK1 of the chamfered opening QK, at least one (e.g., one or more) corners of the upper end SD is recessed.

Exemplarily, an orthogonal projection of the upper end SD of the chamfered opening QK on the base substrate covers an orthogonal projection of the lower end XD of the chamfered opening QK on the base substrate; that is, the size of the upper end SD of the chamfered opening QK is greater than the size of the lower end XD of the chamfered opening QK. Based on this, the chamfered portion QK1 of the chamfered opening QK is arranged obliquely.

In some examples, there are multiple continuous chamfered portions QK1, and the multiple chamfered portions QK1 are connected end to end to form an arc-shaped edge. In a case where the edges of the first pixel opening K1, the second pixel opening K2 and the third pixel opening K3 of the display panel DP each have arc-shaped transitions with less sharp vertex angles, it is possible to ameliorate the visual effect of jaggy lines of the first sub-pixel 610, the second pixel opening 620 and the third sub-pixel 630.

Referring to FIGS. 11A and 11B, in some possible implementations, in an opening unit O, the first pixel opening K1 and the second pixel opening K2 are each a pixel opening having chamfered portions (a chamfered opening QK). The chamfered portions QK1 of the first pixel opening K1 are located on a side of the first pixel opening K1 away from the second pixel opening K2, and the chamfered portions QK1 of the second pixel opening K2 are located on a side of the second pixel opening K2 away from the first pixel opening K1. In order to facilitate the following description, the two chamfered portions of the first pixel opening K1 are respectively referred to as a first chamfered portion QK1(a) and a second chamfered portion QK1(b), and the two chamfered portions of the second pixel opening K2 are respectively referred to as a third chamfered portion QK1(c) and a fourth chamfered portion QK1(d). The first pixel opening K1 may have one of the first chamfered portion QK1(a) and the second chamfered portion QK1(b), and the second pixel opening K2 may have one of the third chamfered portion QK1(c) and the fourth chamfered portion QK1(d). For example, the first pixel opening K1 has the first chamfered portion QK1(a), and the second pixel opening K2 has the third chamfered portion QK1(c). For another example, the first pixel opening K1 has the first chamfered portion QK1(a), and the second pixel opening K2 has the fourth chamfered portion QK1(d). Since a shape of a light-emitting region of each sub-pixel in a pixel 600 is substantially the same as a shape of a respective pixel opening K in an opening unit O, the sharp vertex angle in the outline of the pixel 600 is reduced. Thus, it is possible to ameliorate the visual effect of jaggy lines of image displayed by the display panel.

Based on this, one of the first sub-pixel 610 and the second sub-pixel 620 is a red sub-pixel, and the other is a green sub-pixel. For example, the first sub-pixel 610 is a red sub-pixel, and the second sub-pixel 620 is a green sub-pixel. For another example, the first sub-pixel 610 is a green sub-pixel, and the second sub-pixel 620 is a red sub-pixel. The human eyes are more sensitive to red and green than to blue. Therefore, if the pixel openings K corresponding to the red sub-pixel and the green sub-pixel each have a chamfered portion QK1; further, the chamfered portions QK1 of the two sub-pixels may be respectively located on the sides that away from each other. Thus, it is possible to further ameliorate the visual effect of jaggy lines of image displayed by the display panel.

FIG. 11D is a structural diagram of a pixel opening having chamfered portions. Referring to FIG. 11D, in some possible implementations, the pixel opening having chamfered portions (a chamfered opening QK) is of an axially symmetric structure. A symmetry axis ZL of the pixel opening having chamfered portions (the chamfered opening QK) is parallel to the third direction E. Correspondingly, the light-emitting region of the sub-pixel corresponding to the pixel opening having chamfered portions (the chamfered opening QK) may also be of an axially symmetric structure.

Referring to FIG. 11D, in some possible implementations, the pixel opening having chamfered portions (the chamfered opening QK) also has a third side wall QK4 and a fourth side wall QK5 that are adjacent to the chamfered portion QK1. The chamfered portion QK1 and the third side wall QK4 form a third vertex angle α3, and the chamfered portion QK1 and the fourth side wall QK5 form a fourth vertex angle α4. The third vertex angle α3 is 0.9 to 1.1 times the fourth vertex angle α4. A shape of an orthogonal projection of the pixel opening having chamfered portion (the chamfered opening QK) on the base substrate 100 is an axially symmetrical figure, so that a shape of the orthographic projection of the corresponding sub-pixel on the base substrate 100 is also an axially symmetrical figure. Thus, the display effect of the display panel is more beautiful.

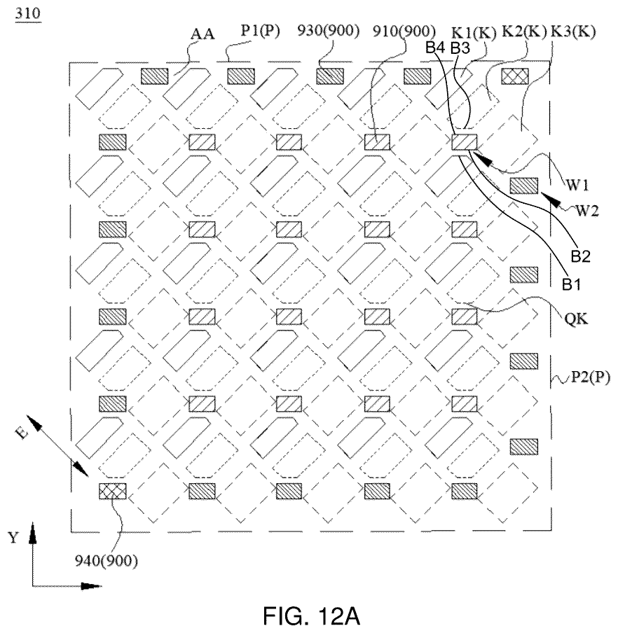

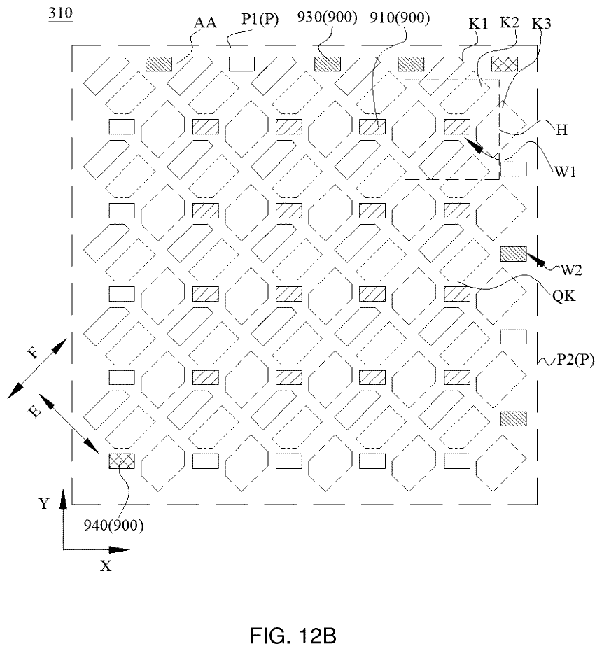

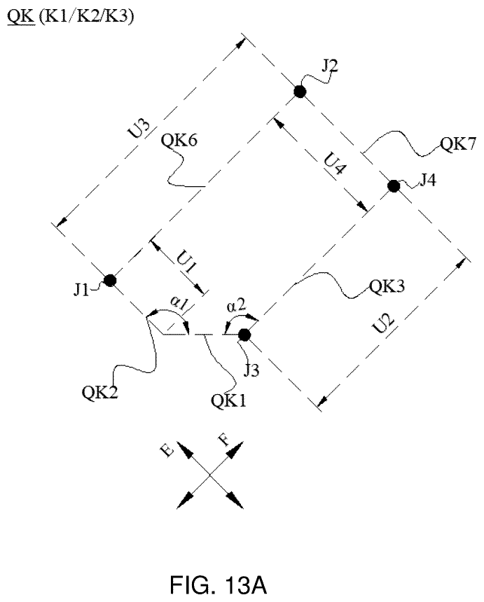

FIG. 12A is a diagram showing an arrangement of spacers and multiple pixel openings, and FIG. 12B is an alternative structural diagram of FIG. 12A. Referring to FIG. 3A and FIGS. 12A to 12B, in some possible implementations, a plurality of spacers 900 are provided on a side of the pixel definition layer 310 away from the base substrate 100. Moreover, the plurality of spacers 900 are located in a region where a portion, except for the plurality of pixel openings K (e.g., the first pixel openings K1, the second pixel openings K2 and the third pixel openings K3), of the pixel definition layer 310 is located. For example, the bottom surface of the spacer 900 is in contact with the top surface of the pixel definition layer 310. For example, the pixel definition layer 310 is formed first, and then the spacers 900 are formed on the pixel definition layer 310, and then the light-emitting layer 322 is formed.

For example, an orthographic projection of the spacer 900 on the pixel definition layer 310 is surrounded by an outline P and the second and third pixel openings K2 and K3 adjacent to each other.

For another example, the orthographic projection of the spacer 900 on the pixel definition layer 310 is surrounded by the outline P and two third pixel openings K3 and one second pixel opening K2 that are adjacent to one other.

For yet another example, the orthographic projection of the spacer 900 on the pixel definition layer 310 is surrounded by the first pixel opening K1, the second pixel opening K2 and the third pixel opening K3 that are adjacent to one other.

For yet another example, the orthographic projection of the spacer 900 on the pixel definition layer 310 is surrounded by the outline P and two first pixel openings K1 and one second pixel opening K2 that are adjacent to one other.

For yet another example, the orthographic projection of the spacer 900 on the pixel definition layer 310 is surrounded by the first pixel opening K1, the second pixel opening K2 and two third pixel openings K3 that are adjacent to one other.

The term “an orthographic projection of A on B” herein refers to a projection of A on B in a direction perpendicular to a plane where B is located. For example, the orthographic projection of the spacer 900 on the pixel definition layer 310 refers to a projection of the spacer 900 on the pixel definition layer 310 in a thickness direction of the pixel definition layer 310.

The spacer 900 in these embodiments is used to support a fine metal mask (FMM) when the light-emitting materials are evaporated, and in these embodiments, the arrangement of the spacers 900 is adapted to the arrangement of the sub-pixels. In addition, in these embodiments, the spacers 900 are disposed between a contour P and the sub-pixels proximate to the contour P. Thus, it is possible to increase the number of spacers 900 while the space is fully utilized, thereby improving the stability for supporting the FMM.

Referring to FIGS. 12A and 12B, some embodiments of the present disclosure provide a display panel 100. The plurality of spacers 900 of the display panel DP include a plurality of first spacers 910. The first spacers 910 are each located between two third pixel openings K3 that are arranged in the first direction X and adjacent to each other. Moreover, the first spacers 910 are each located between the first pixel opening K1 and the second pixel opening K2 that are arranged in the second direction Y and adjacent to each other. For the convenience of the following description, a position where the first spacer 910 is located is referred to as a first position W1. That is, the first position W1 is an intersection position of two third pixel openings K3 that are arranged in the first direction X and adjacent to each other and the first pixel opening K1 and the second pixel opening K2 that are arranged in the second direction Y and adjacent to each other. In this way, the first spacer 910 is surrounded by the two third pixel openings K3, the first pixel opening K1 and the second pixel opening K2 at the first position W1. For example, there is a first spacer 910 at each first position W1. In addition, these first spacers 910 are arranged in an array. Thus, the first spacers 910 are arranged evenly, which is beneficial to improving the stability for supporting the FMM.

Referring to FIGS. 12A and 12B, in some possible implementations, at the first position W1, at least one of the first pixel opening K1, the second pixel opening K2 and the third pixel opening K3 that are adjacent to the first spacer 910 is a pixel opening having a chamfered portion (a chamfered opening QK). The chamfered portion is located at a position (i.e., the first position W1), that is proximate to the first spacer 910, of the pixel opening. For example, the first pixel opening K1, the second pixel opening K2 and the two third pixel openings K3 that are proximate to the first position W1 may each be a pixel opening QK having a chamfered portion, and may each have a chamfered portion QK1. For another example, the first pixel opening K1 and the second pixel opening K2 that are proximate to the first position W1 may each be a pixel opening having a chamfered portion (the chamfered opening QK), and each have a chamfered portion QK1; the third pixel opening K3 is not a chamfered opening QK. For yet another example, the first pixel opening K1 proximate to the first position W1 is a chamfered opening QK and has a chamfered portion QK1; the second pixel opening K2 and the third pixel opening K3 are not chamfered openings QK. For yet another example, the second pixel opening K2 proximate to the first position W1 is a chamfered opening QK and has a chamfered portion QK1; the first pixel opening K1 and the third pixel opening K3 are not chamfered openings QK. For yet another example, the two third pixel openings K3 proximate to the first position W1 are chamfered openings QK, and each have a chamfered portion QK1; the first pixel opening K1 and the second pixel opening K2 are not chamfered openings QK.

In addition, an orthogonal projection of the chamfered portion QK1 on the base substrate 100 is non-overlapping with an orthographic projection of the first spacer 910 on the base substrate 100. For example, orthographic projections, on the base substrate, of the chamfered portion of the first pixel opening K1 and the chamfered portion of the second pixel opening K2 that are proximate to the first position W1 are non-overlapping with the orthographic projection of the first spacer 910 on the base substrate. The orthographic projections of the chamfered portions of the two third pixel openings K3 proximate to the first position W1 on the base substrate are non-overlapping with the orthographic projection of the first spacer 910 on the base substrate. For yet another example, the orthographic projections, on the base substrate, of the chamfered portion of the first pixel opening K1 and the chamfered portion of the second pixel opening K2 that are proximate to the first position W1 are non-overlapping with the orthographic projection of the first spacer 910 on the base substrate.

In these embodiments, at least one of the first pixel opening K1, the second pixel opening K2 and the third pixel opening K3 that are adjacent to the first spacer 910 is a pixel opening having a chamfered portion (a chamfered opening QK). In this way, the first pixel opening K1, the second pixel opening K2, and the third pixel opening K3 are adjusted adaptively with the first spacer 910, thereby increasing the area of the first spacer 910 to improve the stability for supporting the FMM.

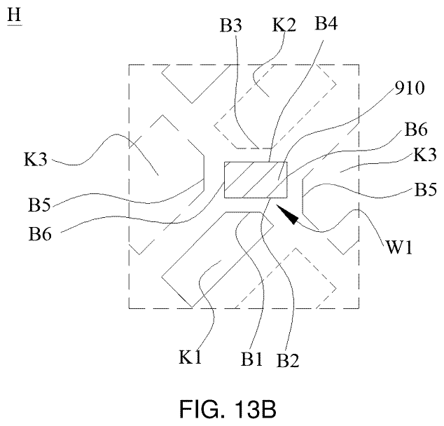

FIG. 13A is a structural diagram of a pixel opening having a chamfered portion in FIG. 12B. Referring to FIGS. 12A to 13A, in some possible implementations, a pixel opening having a chamfered portion (a chamfered opening QK) (for example, the first pixel opening K1 being a chamfered opening QK; for another example, the second pixel opening K2 being a chamfered opening QK; for yet another example, the third pixel opening K3 is a chamfered opening QK) has a first side wall QK2 and a second side wall QK3 that are adjacent to the chamfered portion QK1. The chamfered portion and the first side wall QK2 form a first vertex angle α1, and the chamfered portion and the second side wall QK3 form a second vertex angle α2, and the first vertex angle α1 is 0.9 times to 1.1 times the second vertex angle α2.

Referring to FIG. 13A, in some possible implementations, the pixel opening K having a chamfered portion QK1 (a chamfered opening QK) further includes: a fifth side wall QK6 opposite to the second side wall QK3 in the third direction E, and a sixth side wall QK7 opposite to the first side wall QK2 in a fourth direction F; the fourth direction F and the third direction E intersect, for example, being perpendicular to each other. A difference between a dimension (referred to as a third dimension U3) of the fifth side wall QK6 in the fourth direction F and a dimension (referred to as a second dimension U2) of the second side wall QK3 in the fourth direction F is a first difference, a difference between a dimension (referred to as a fourth dimension U4) of the sixth side wall QK7 in the third direction E and a dimension (referred to as a first dimension U1) of the first side wall QK2 in the third direction E is a second difference, and the first difference is equal to the second difference. That is, U3−U2=U4−U1. The first dimension U1, the second dimension U2, the third dimension U3 and the fourth dimension U4 all refer to a size of the lower end of the pixel opening K.

Referring to FIG. 12B, a line connecting geometric centers of two adjacent (e.g., every two adjacent, or some two adjacent) pixel openings in the first direction X that each having a chamfered portion QK1 and that corresponding to the sub-pixels emitting light of a same color is parallel to the first direction X. For example, a line connecting the geometric centers of two adjacent first pixel openings K1 in the first direction X is parallel to the first direction X. For another example, a line connecting the geometric centers of two adjacent second pixel openings K2 in the first direction X is parallel to the first direction X. For yet another example, a line connecting the geometric centers of two adjacent third pixel openings K3 in the first direction X is parallel to the first direction X.

Exemplarily, a line connecting geometric centers of two adjacent (e.g., every two adjacent, or some two adjacent) pixel openings (e.g., two adjacent first pixel openings K1, two adjacent second pixel openings K2, or two adjacent third pixel openings K3) in the second direction Y that each having a chamfered portion QK1 and that corresponding to the sub-pixels emitting light of a same color is parallel to the second direction Y.

Exemplarily, a line connecting geometric centers of two adjacent (e.g., every two adjacent, or some two adjacent) pixel openings (e.g., two adjacent first pixel openings K1, two adjacent second pixel openings K2, or two adjacent third pixel openings K3) in the first direction X that each having a chamfered portion QK1 and corresponding to the sub-pixels emitting light of a same color is parallel to the first direction X. Moreover, a line connecting geometric centers of two adjacent (e.g., every two adjacent, or some two adjacent) pixel openings (e.g., two adjacent first pixel openings K1, two adjacent second pixel openings K2, or two adjacent third pixel openings K3) in the second direction Y that each having a chamfered portion QK1 and corresponding to the sub-pixels emitting light of a same color is parallel to the second direction Y.

Referring to FIGS. 12B and 13A, in some possible implementations, in the first direction X or the second direction Y, for two adjacent (e.g., every two adjacent, or some two adjacent) pixel openings, that each having a chamfered portion QK1 and that corresponding to the sub-pixels emitting light of a same color, a chamfered portion QK1 included in each of the two adjacent pixel openings is located at a same corner position of the respective pixel opening of the two adjacent pixel openings. The pixel opening K has a first corner J1, a second corner J2, a third corner J3, and a fourth corner J4. For example, the chamfered portions QK1 of every two adjacent first pixel openings K1, in the first direction X or the second direction X, are each located at a position of the second corner J2 of the respective first pixel opening K1. For another example, chamfered portions QK1 of each of every two adjacent third pixel openings K3, in the first direction X, are respectively located at positions of the first corner J1 and fourth corner J4 of the respective third pixel opening K3. For yet another example, chamfered portions QK1 of each of some two adjacent third pixel openings K3, in the first direction X, are respectively located at positions of the first corner J1 and fourth corner J4 of the respective third pixel opening K3.

Referring to FIG. 12B, for example, in a case where the chamfered portion QK1 included in each of the two adjacent pixel openings is located at the position of the same corner of the respective pixel opening of the two adjacent pixel openings, the two adjacent pixel openings (e.g., two adjacent first pixel openings K1, two adjacent second pixel openings K2, or two adjacent third pixel openings K3) have the same shape and the same size. Referring to FIG. 11B, in some possible implementations, the first sub-pixel 610, the second sub-pixel 620 and the third sub-pixel 630 in the pixel 600 all extend in the fourth direction F. The fourth direction F and the third direction E form an angle in a range of 80° to 100°, inclusive.

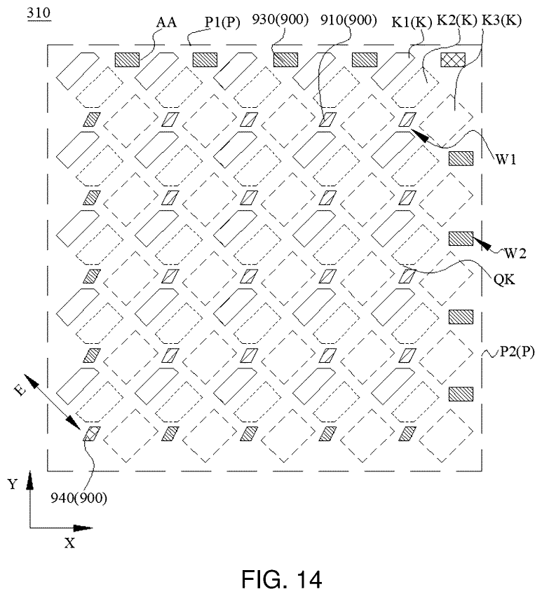

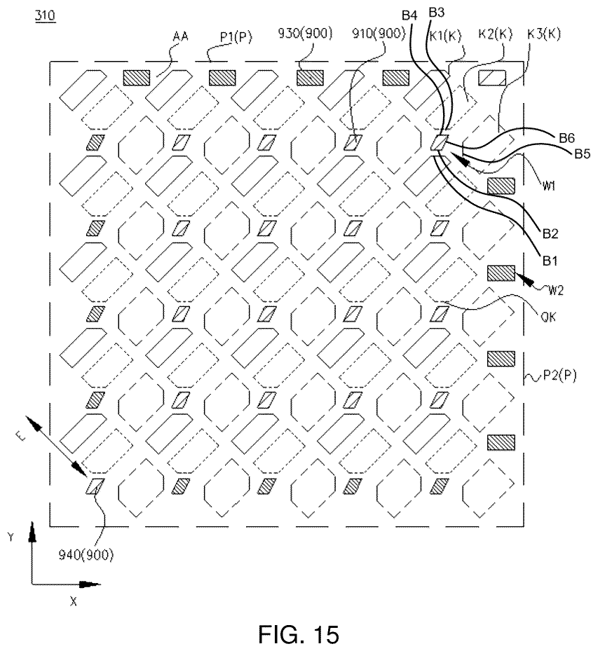

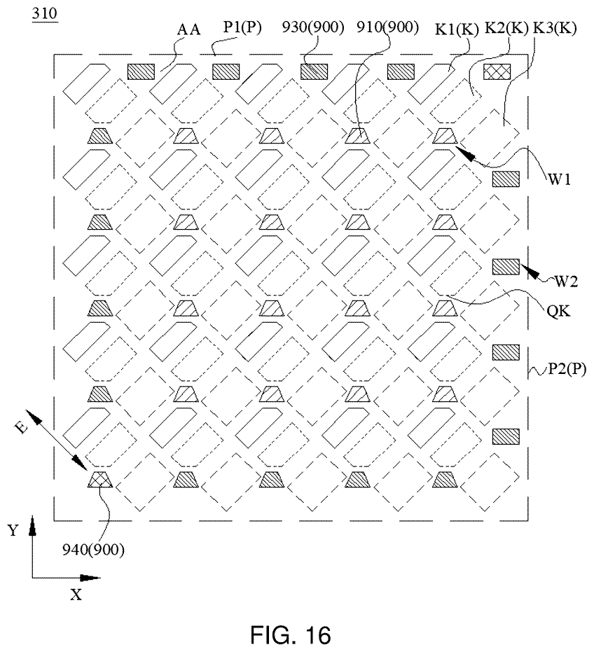

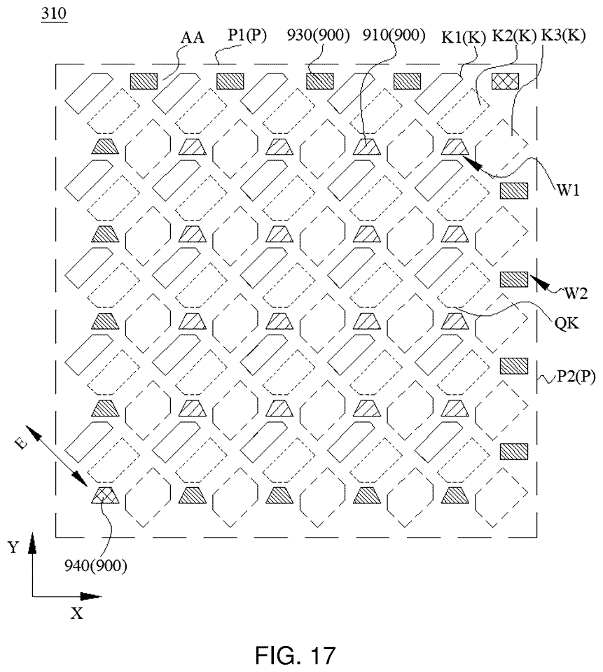

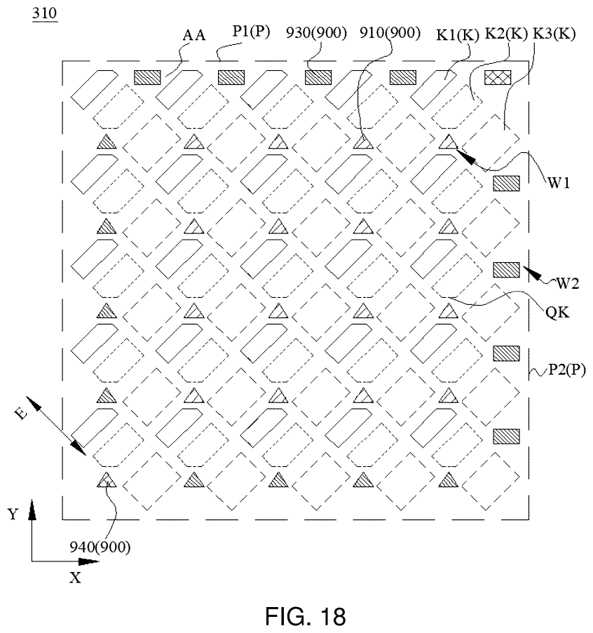

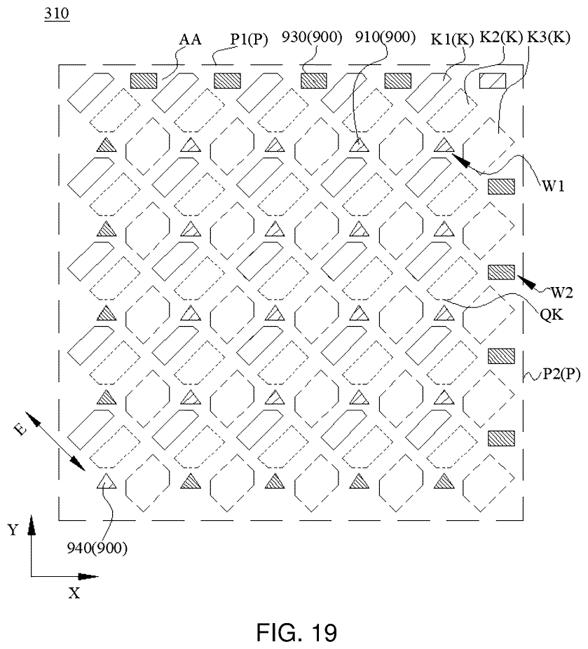

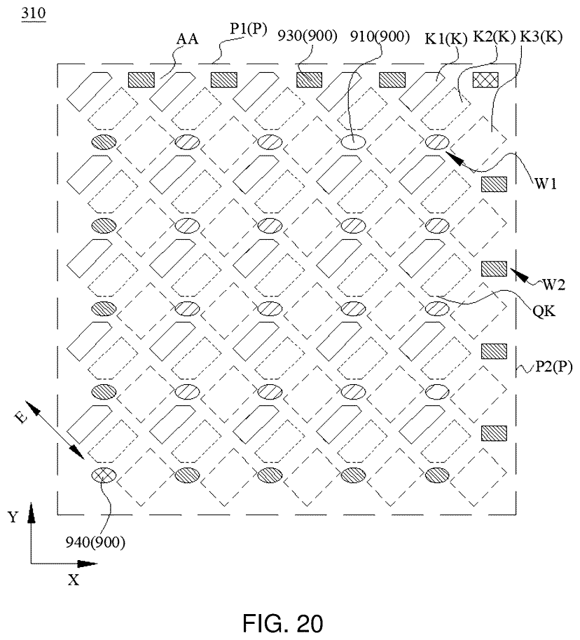

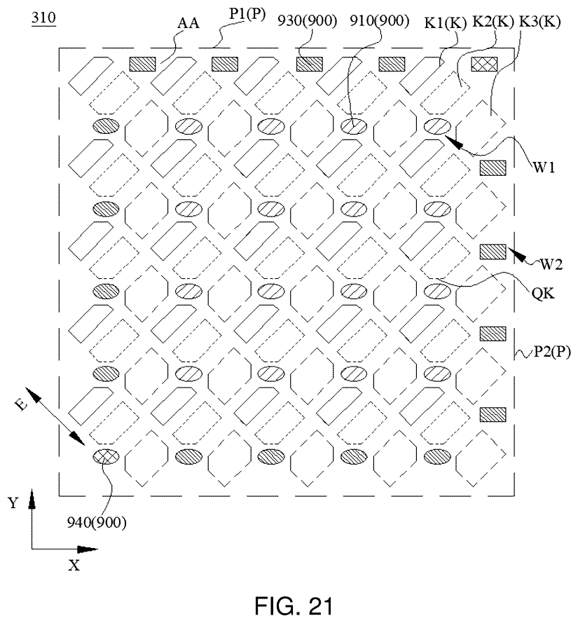

FIG. 13B is a partial enlarged view of the region H in FIG. 12B; FIG. 14 is another alternative structural diagram of FIG. 12A; FIG. 15 is yet another alternative structural diagram of FIG. 12A; FIG. 16 is yet another alternative structural diagram of FIG. 12A; FIG. 17 is yet another alternative structural diagram of FIG. 12A; FIG. 18 is yet another alternative structural diagram of FIG. 12A; FIG. 19 is yet another alternative structural diagram of FIG. 12A; FIG. 20 is yet another alternative structural diagram of FIG. 12A; and FIG. 21 is yet another alternative structural diagram of FIG. 12A.

Referring to FIGS. 12A and 12B, and FIGS. 13B to 21, in some possible implementations, the first pixel opening K1 adjacent to the first spacer 910 is a pixel opening having a chamfered portion (a chamfered opening QK). An orthographic projection of the first spacer 910 on the pixel definition layer 310 and the first pixel opening K1 on the each have a side, and the two sides are close to each other and substantially parallel to each other. That is, the first pixel opening K1 has a first side B1 proximate to the first position W1; the orthographic projection of the first spacer 910 on the pixel definition layer 310 has a second side B2 proximate to the first position W1; the first side B1 is substantially parallel to the second side B2.

Exemplarily, the first pixel opening K1 adjacent to the first spacer 910 is a pixel opening having a chamfered portion (a chamfered opening QK). The chamfered portion of the first pixel opening K1 is substantially parallel to the first direction X. That is, the chamfered portion of the first pixel opening K1 that is proximate to the first position W1 is substantially parallel to the first direction X.

As another example, the first pixel opening K1 adjacent to the first spacer 910 is a pixel opening having a chamfered portion (a chamfered opening QK). An orthographic projection of the first spacer 910 on the pixel definition layer 310 and the first pixel opening K1 each have a side, and the two sides are close to each other and substantially parallel to each other. That is, the first pixel opening K1 has a first side B1 proximate to the first position W1; the orthographic projection of the first spacer 910 on the pixel definition layer 310 has a second side B2 proximate to the first position W1; the first side B1 is substantially parallel to the second side B2.

Moreover, the first pixel opening K1 adjacent to the first spacer 910 is a pixel opening having a chamfered portion (a chamfered opening QK). The chamfered portion of the first pixel opening K1 is substantially parallel to the first direction X. That is, the chamfered portion of the first pixel opening K1 that is proximate to the first position W1 is substantially parallel to the first direction X.

In these embodiments, the stability for supporting the FMM is improved, and the reasons will be referred to the embodiments described above and will not be repeated here.

Referring to FIGS. 12A and 12B, FIGS. 13B to 17, and FIGS. 20 to 21, in some possible implementations, the second pixel opening K2 adjacent to the first spacer 910 is a pixel opening having chamfered portion(s) (a chamfered opening QK). An orthographic projection of the first spacer 910 on the pixel definition layer 310 and the second pixel opening K2 each have a side, and the two sides are close to each other and substantially parallel to each other. That is, the second pixel opening K2 has a third side B3 proximate to the first position W1; the orthographic projection of the first spacer 910 on the pixel definition layer 310 has a fourth side B4; the third side B3 is substantially parallel to the fourth side B4.

For example, the second pixel opening K2 adjacent to the first spacer 910 is a pixel opening having a chamfered portion (a chamfered opening QK), and the chamfered portion of the second pixel opening K2 is substantially parallel to the first direction. That is, the chamfered portion of the second pixel opening K2 that is proximate to the first position W1 is substantially parallel to the first direction X.

As another example, the second pixel opening K2 adjacent to the first spacer 910 is a pixel opening having a chamfered portion (a chamfered opening QK). An orthographic projection of the first spacer 910 on the pixel definition layer 310 and the second pixel opening K2 each have a side, and the two sides are close to each other and substantially parallel to each other. That is, the second pixel opening K2 has a third side B3 proximate to the first position W1; the orthographic projection of the first spacer 910 on the pixel definition layer 310 has a fourth side B4 proximate to the first position W1; the third side B3 is substantially parallel to the fourth side B4.

Moreover, the second pixel opening K2 adjacent to the first spacer 910 is a pixel opening having a chamfered portion (a chamfered opening QK), and the chamfered portion of the second pixel opening K2 is substantially parallel to the first direction. That is, the chamfered portion of the second pixel opening K2 that is proximate to the first position W1 is substantially parallel to the first direction X. Effects achieved in the embodiments are the same as the effects achieved in the embodiments above, and will not be repeated here.

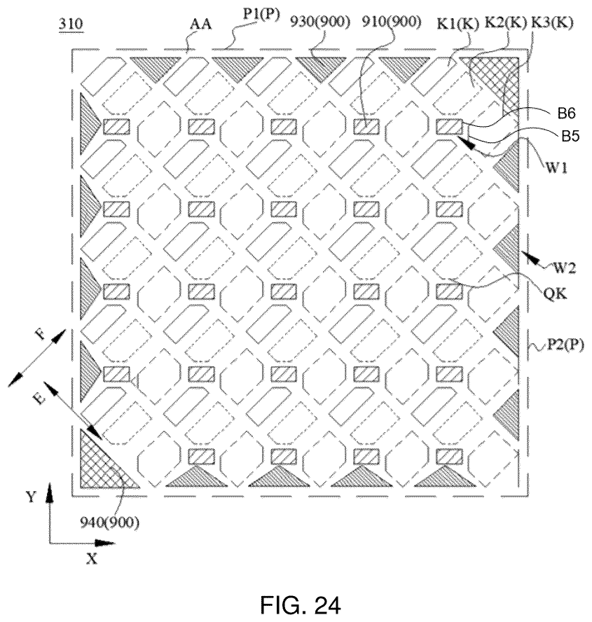

Referring to FIGS. 15 and 24, in some possible implementations, the third pixel opening K3 adjacent to the first spacer 910 is a pixel opening having chamfered portions (a chamfered opening QK). An orthographic projection of the first spacer 910 on the pixel definition layer 310 and the third pixel opening K3 each have a side, and the two sides are close to each other and substantially parallel to each other. That is, the third pixel opening K3 has a fifth side B5 proximate to the first position W1; the orthographic projection of the first spacer 910 on the pixel definition layer 310 has a sixth side B6 proximate to the first position W1; the fifth side B5 is substantially parallel to the sixth side B6.

Exemplarily, the third pixel opening K3 adjacent to the first spacer 910 is a pixel opening having chamfered portions (a chamfered opening QK), and the chamfered portion of the third pixel opening K3 is substantially parallel to the second direction Y. That is, the chamfered portion of the third pixel opening K3 that is proximate to the first position W1 is substantially parallel to the second direction Y.

As another example, the third pixel opening K3 adjacent to the first spacer 910 is a pixel opening having chamfered portions (a chamfered opening QK). An orthographic projection of the first spacer 910 on the pixel definition layer 310 and the third pixel opening K3 each have a side, and the two sides are close to each other and substantially parallel to each other. That is, the third pixel opening K3 has a fifth side B5 proximate to the first position W1; the orthographic projection of the first spacer 910 on the pixel definition layer 310 has a sixth side D6 proximate to the first position W1; the fifth side B5 is substantially parallel to the sixth side B6.

Moreover, the third pixel opening K3 adjacent to the first spacer 910 is a pixel opening having chamfered portions (a chamfered opening QK), and the chamfered portion of the third pixel opening K3 is substantially parallel to the second direction Y. That is, the chamfered portion of the third pixel opening K3 that is proximate to the first position W1 is substantially parallel to the second direction Y. Effects achieved in the embodiments are the same as the effects achieved in the embodiments above, and will not be repeated here.

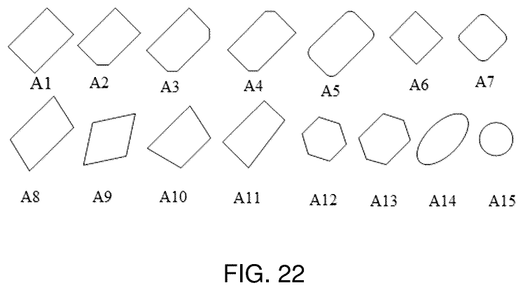

FIG. 22 is a diagram showing possible shapes of the orthographic projection of the first spacer on the pixel definition layer. Referring to FIGS. 12A to 12B and FIGS. 14 to 22, in some possible implementations, the shapes of the orthographic projections of the first spacers 910 on the pixel definition layer 310 includes one or more pattern types of a triangle, a rectangle (A1 to A5 in FIG. 22), square (A6 and A7 in FIG. 22), parallelogram (A8 and A9 in FIG. 22), rhombus (A9 in FIG. 22), trapezoid (A10 and A11 in FIG. 22), pentagon, hexagon (A12 and A13 in FIG. 22), ellipse (A14 in FIG. 22), or circle (A15 in FIG. 22). For example, if the orthographic projection of the first spacer 910 on the pixel definition layer 310 is a pattern type of a rectangle, it means that the orthographic projection of the first spacer 910 on the pixel definition layer 310 is substantially in a shape of a rectangle, such as a standard rectangle (A1 in FIG. 22), or a quasi-rectangle with chamfers or rounded corners (A2 to A5 in FIG. 22). For another example, if the orthographic projection of the first spacer 910 on the pixel definition layer 310 is a pattern type of a square, it means that the orthographic projection of the first spacer 910 on the pixel definition layer 310 is substantially in a shape of a square, such as a standard square (A6 in FIG. 22) or a quasi-square with chamfers or rounded corners (A7 in FIG. 22).

FIG. 12B shows some possible shapes of the orthographic projection of the first spacer 910 on the pixel definition layer 310, and the shapes of the orthographic projection of the first spacer 910 on the pixel definition layer 310 protected by these embodiments are not limited thereto.

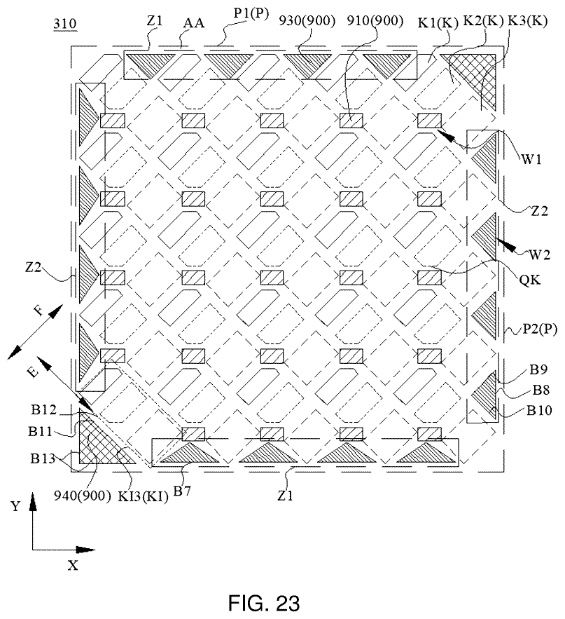

FIG. 23 is yet another alternative structural diagram of FIG. 12A; FIG. 24 is yet another alternative structural diagram of FIG. 12A. Referring to FIGS. 23 and 24, some embodiments of the present disclosure provide a display panel 100. The display area AA of the display panel DP has a contour P, and the plurality of spacers 900 are located in the display area AA. The plurality of spacers 900 include a plurality of third spacers 930. The third spacers 930 are each located between two adjacent pixel openings K (e.g., two adjacent third pixel openings K3, a second pixel opening K2 and an adjacent first pixel opening K1, or two adjacent first pixel openings K1) proximate to the contour P.

It will be noted that the display area AA has a first contour P1 extending in the first direction X and a second contour P2 extending in the second direction Y. The third spacers 930 are divided into a first spacer group Z1 extending in the first direction X and a second spacer group Z2 extending in the second direction Y. Both the first spacer group Z1 and the second spacer group Z2 include at least one third spacer 930. For example, the third spacer 930 in the first spacer group Z1 is located between two adjacent pixel openings K proximate to the first contour P1. For another example, the third spacer 930 in the second spacer group Z2 is located between two adjacent pixel openings K proximate to the second contour P2.

In these embodiments, if allowed, the space may be used to arrange the third spacers 930 as much as possible, and the spacers 900 may be arranged both inside and on the edge of the display area AA. Thus, the arrangement density of spacers 900 is improved to improve the stability for supporting the FMM.

Referring to FIGS. 23 and 24, in some possible implementations, the orthographic projection of the third spacer 930 on the pixel definition layer 310 has a side proximate to and substantially parallel to the contour P. For example, the orthographic projection of the third spacer 930 in the first spacer group Z1 on the pixel definition layer 310 has a seventh side B7, and the seventh side B7 is substantially parallel to the first contour P1. For another example, the orthographic projection of the third spacer 930 in the second spacer group Z2 on the pixel definition layer 310 has an eighth side B8, and the eighth side B8 is substantially parallel to the second contour P2.

In these embodiments, in the same arrangement space, the area of the third spacer 930 may be increased as much as possible to improve the stability of the third spacer 930 supporting the FMM.

Referring to FIGS. 23 and 24, in some possible implementations, one of two adjacent pixel openings K proximate to the contour P and an orthographic projection of the third spacer 930 on the pixel definition layer 310 each have a side, and the two sides are close to each other and parallel to each other. For convenience of description below, a position where the third spacer 930 is disposed is referred to as a second position W2. The second position W2 is located between the two adjacent pixel openings K and the contour P. That is, at a position proximate to the second position W2, one or two of the two adjacent pixel openings K and an orthographic projection of the third spacer 930 on the pixel definition layer 310 each have a side, and the two sides are close to each other and parallel to each other. For example, at a position proximate to the second position W2, the orthographic projection of the third spacer 930 on the pixel definition layer 310 has a ninth side B9 and a tenth side B10. The ninth side B9 and the tenth side B10 are each parallel to a respective one of sides of the two adjacent pixel openings K proximate to the second position W2. Effects achieved in the embodiments are the same as the effects achieved in the embodiments above, and will not be repeated here.

Referring to FIGS. 12A to 12B, FIGS. 14 to 21, and FIGS. 23 to 24, in some possible implementations, the shapes of the orthographic projections of the third spacers 930 on the pixel definition layer 310 include one or more pattern types of a triangle, rectangle, square, parallelogram, trapezoid, and ellipse. In a same space, the space is utilized as much as possible to arrange the third spacers 930.

Referring to FIGS. 12A to 12B, FIGS. 14 to 21, and FIGS. 23 to 24, embodiments of the present disclosure provide a display panel DP. In a case where the display panel DP includes the first spacers 910 and the third spacers 930, the shapes of the orthographic projections of the first spacer 910 and the third spacer 930 on the pixel definition layer 310 are different. For example, the orthographic projection of the first spacer 910 on the pixel definition layer 310 is in a shape of a rectangle, and the orthographic projection of the third spacer 930 on the pixel definition layer 310 is in a shape of a triangle. For another example, the orthographic projection of the first spacer 910 on the pixel definition layer 310 is in a shape of a trapezoid, and the orthographic projection of the third spacer 930 on the pixel definition layer 310 is in a shape of a rectangle.

For example, in a case where the display panel DP includes the first spacers 910 and the fourth spacers 940, the shapes of the orthographic projections of the first spacer 910 and the fourth spacer 940 on the pixel definition layer 310 are different. For example, the orthographic projection of the first spacer 910 on the pixel definition layer 310 is in a shape of a rectangle, and the orthographic projection of the fourth spacer 940 on the pixel definition layer 310 is in a shape of a triangle. For another example, the orthographic projection of the first spacer 910 on the pixel definition layer 310 is in a shape of a trapezoid, and the orthographic projection of the fourth spacer 940 on the pixel definition layer 310 is in a shape of a triangle.

For example, in a case where the display panel DP includes first spacers 910, third spacers 930 and fourth spacers 940, the shapes of the orthographic projections of the first spacer 910 and the third spacer 930 on the pixel definition layer 310 are different, and the shapes of the orthographic projections of the first spacer 910 and the fourth spacer 940 on the pixel definition layer 310 are different. For example, the orthographic projection of the first spacer 910 on the pixel definition layer 310 is in a shape of a rectangle, and the orthographic projections of the third spacer 930 and the fourth spacer 940 on the pixel definition layer 310 are each in a shape of a triangle. For another example, the orthographic projection of the first spacer 910 on the pixel definition layer 310 is in a shape of a trapezoid, and the orthographic projections of the third spacer 930 and the fourth spacer 940 on the pixel definition layer 310 are each in a shape of a rectangle.

Referring to FIGS. 12A to 12B, FIGS. 14 to 21, and FIGS. 23 to 24, embodiments of the present disclosure provide a display panel DP. In a case where the display panel DP includes the first spacers 910 and the third spacers 930, the orthographic projections of the first spacer 910 and the third spacer 930 on the pixel definition layer 310 have the same shape and the same size. For example, the orthographic projections of the first spacer 910 and the third spacer 930 on the pixel definition layer 310 are each in a shape of a rectangle with a same size.

Referring to FIGS. 23 and 24, some embodiments of the present disclosure provide a display panel DP. The plurality of pixel openings K of the display panel DP are divided into a plurality of opening groups KI arranged in the fourth direction F. For example, the fourth direction F is perpendicular to the third direction E.

The plurality of spacers 900 further include at least one fourth spacer 940. The fourth spacer 940 is located between an opening group of the plurality of opening groups KI that is located at the outermost of the display panel DP and the contour P. For convenience of description below, the opening group KI located at the outermost of the display panel DP is referred to as a third opening group KI3. The fourth spacer 940 is located between the third opening group KI3 and the contour P. In this way, the fourth spacer 940 is surrounded by the third opening group KI3 and the contour P. In these embodiments, the fourth spacer 940 is arranged between the third opening group KI3 and the contour P, thereby utilizing the space in this region to increase the density of the spacers 900 and improve the stability for supporting the FMM.

Referring to FIGS. 23 and 24, in some possible implementations, an orthographic projection of the fourth spacer 940 on the pixel definition layer 310 and the opening group KI located at the outermost edge of the display panel each have a side, and the two sides are close to each other and substantially parallel to each other. That is, the orthographic projection of the fourth spacer 940 on the pixel definition layer 310 and the orthogonal projection of the third opening group KI3 on the pixel definition layer 310 each have a side, and the sides are close to each other and substantially parallel to each other. For example, the orthographic projection of the fourth spacer 940 on the pixel definition layer 310 has an eleventh side B11, and the orthogonal projection of the third opening group KI3 on the pixel definition layer 310 has a twelfth side B12; the eleventh side B11 and the twelfth side B12 are close to each other and substantially parallel to each other.

Referring to FIGS. 23 and 24, in some possible implementations, the orthographic projection of the fourth spacer 940 on the pixel definition layer 310 has a side that is proximate to and substantially parallel to the contour P. For example, the orthographic projection of the fourth spacer 940 on the pixel definition layer 310 has a thirteenth side B13, and the thirteenth side B13 and the contour P are close to each other and substantially parallel to each other.

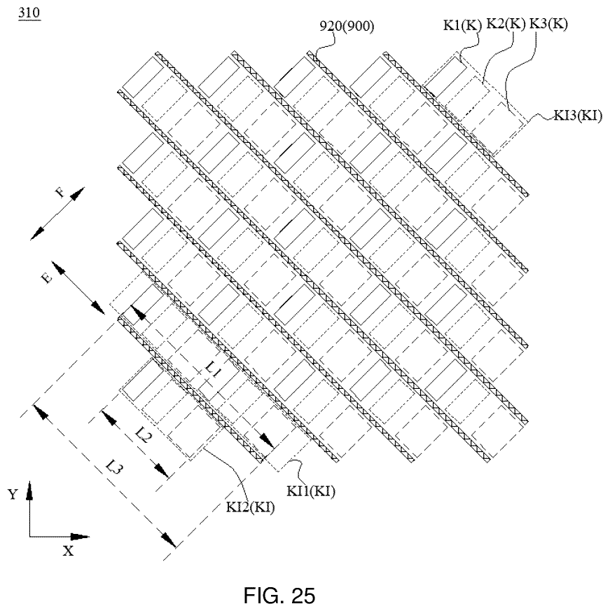

FIG. 25 is yet another alternative structural diagram of FIG. 12A. Referring to FIG. 25, in some possible implementations, the plurality of pixel openings K are divided into a plurality of opening groups KI arranged in the fourth direction F. A (e.g., each) opening group KI includes at least one (e.g., one or more) pixel opening K. The plurality of spacers 900 includes at least one (e.g., one or more) second spacer 920. The second spacer 920 is in a shape of a strip and extends in the third direction E between two adjacent opening groups KI.

In these embodiments, due to the second spacer 920 that is in a shape of a strip, the second spacers 920 are arranged more uniformly, so that the stability for supporting the FMM is further improved.

Referring to FIG. 25, in some possible implementations, two adjacent opening groups KI include a first opening group KI1 and a second opening group KI2. A length L1 of the first opening group KI1 in the third direction E is greater than a length L2 of the second opening group KI2 in the third direction E. A length L3 of the second spacer 920 in the third direction E is less than or equal to the length L1 of the first opening group KI1 in the third direction E, and is greater than or equal to the length L2 of the second opening group KI2 in the third direction E.

Referring to FIG. 25, in some possible implementations, the orthographic projection of the second spacer 920 on the pixel definition layer 310 and the first opening group KI1 each have two ends, and the two ends of one of the two are respectively flush with the two ends of the other of the two. That is, the orthographic projections of the two ends of the second spacer 920 on the pixel definition layer 310 are respectively flush with the two ends of the first opening group KI1. In this way, the second spacer 920 is able to support the FMM in the entire length of the first opening group KI1, thereby improving the stability for supporting the FMM. In addition, the arrangement of the second spacers 920 is made more uniform, thereby further improving the stability for supporting the FMM.

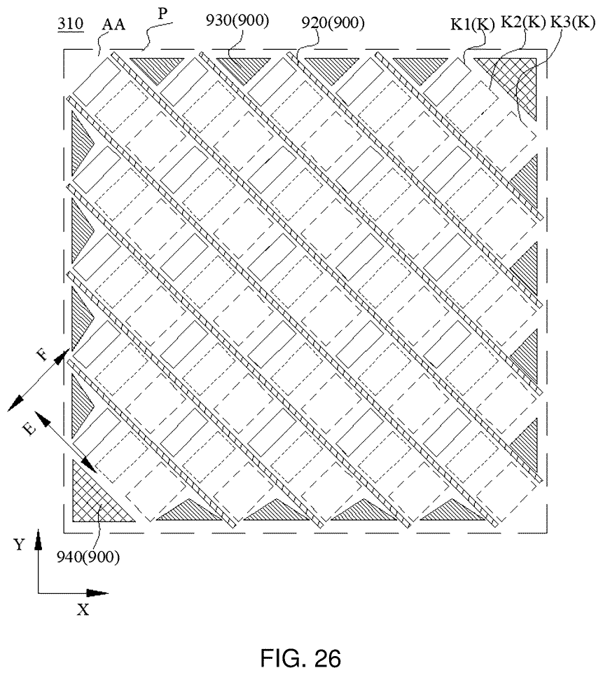

FIG. 26 is yet another alternative structural diagram of FIG. 25. Referring to FIG. 26, in some possible implementations, the plurality of spacers 900 include second spacers 920, third spacers 930 and fourth spacers 940. For related descriptions of the third spacers 930 and the fourth spacers 940, reference may be made to the foregoing embodiments and will not be repeated here.

The above are only specific embodiments of the present disclosure, but the scope of protection of the present disclosure is not limited thereto, and any person skilled in the art may conceive of variations or replacements within the technical scope of the present disclosure, which shall fall within the protection scope of the present disclosure. Therefore, the protection scope of the present disclosure should be determined by the protection scope of the claims.

1. A display panel, comprising:
a base substrate;
a pixel definition layer disposed on the base substrate, the pixel definition layer including a plurality of pixel openings, the plurality of pixel openings including first pixel openings, second pixel openings and third pixel openings; and
a plurality of pixels disposed on the base substrate, the plurality of pixels being arranged in M rows and N columns, a row of the M rows including N pixels arranged in a first direction, and a column of the N columns including M pixels arranged in a second direction; M≥2, and N≥2, the first direction intersecting with the second direction; wherein a pixel of the plurality of pixels includes a plurality of sub-pixels emitting light of different colors, the plurality of sub-pixels include a first sub-pixel located at a first pixel opening of the first pixel openings, a second sub-pixel located at a second pixel opening of the second pixel openings, and a third sub-pixel located at a third pixel opening of the third openings; the first sub-pixel, the second sub-pixel and the third sub-pixel are arranged sequentially in a third direction, the third direction intersecting with both the first direction and the second direction; for all sub-pixels included in the plurality of pixels, in the third direction, two adjacent sub-pixels that emit light of a same color are separated by at least two sub-pixels that emit light of another colors, and the at least two sub-pixels emit light of colors that are different from each other.

2. The display panel according to claim 1, further comprising:
a plurality of spacers located on a side of the pixel definition layer away from the base substrate and located in a region where a portion, except for the plurality of pixel openings, of the pixel definition layer is located.

3. The display panel according to claim 2, wherein
the plurality of spacers include a plurality of first spacers;
a first spacer of the first spacers is located between two third pixel openings arranged in the first direction and adjacent to each other and between a first pixel opening and a second pixel opening that are arranged in the second direction and adjacent to each other.

4. The display panel according to claim 3, wherein
at least one of the first pixel opening, the second pixel opening and the third pixel openings that are adjacent to the first spacer is a pixel opening having a chamfered portion; wherein
the chamfered portion is located at a position of the pixel opening proximate to the first spacer; an orthogonal projection of the chamfered portion on the base substrate is non-overlapping with an orthographic projection of the first spacer on the base substrate.

5. The display panel according to claim 4, wherein
the pixel opening having the chamfered portion further includes a first side wall and a second side wall that are adjacent to the chamfered portion; the chamfered portion and the first side wall form a first vertex angle, and the chamfered portion and the second side wall form a second vertex angle; the first vertex angle is 0.9 times to 1.1 times the second vertex angle.

6. The display panel according to claim 4, wherein
the pixel opening having the chamfered portion further includes a fifth side wall opposite to the second sidewall in the third direction and a sixth side wall opposite to the first side wall in a fourth direction, the fourth direction intersecting with the third direction; wherein
a difference between a dimension of the fifth side wall in the fourth direction and a dimension of the second side wall in the fourth direction is a first difference, and a difference between a dimension of the sixth side wall in the third direction and a dimension of the first side wall in the third direction is a second difference; the first difference is equal to the second difference.

7. The display panel according to claim 4, wherein at least two of the first pixel opening, the second pixel opening and the third pixel openings that are adjacent to the first spacer is a pixel opening having a chamfered portion; wherein
a line connecting geometric centers of two adjacent pixel openings in the first direction that each having a chamfered portion and that corresponding to sub-pixels emitting light of a same color of all the sub-pixels is parallel to the first direction; and/or
a line connecting geometric centers of two adjacent pixel openings in the second direction that each having a chamfered portion and that corresponding to sub-pixels emitting light of a same color of all the sub-pixels is parallel to the second direction.

8. The display panel according to claim 4, wherein at least two of the first pixel opening, the second pixel opening and the third pixel openings that are adjacent to the first spacer is a pixel opening having a chamfered portion; wherein
in the first direction or the second direction, for two adjacent pixel openings that are each having a chamfered portion and corresponding to sub-pixels emitting light of a same color of all the sab-pixels, a chamfered portion included in each of the two adjacent pixel openings is located at a same corner position of a respective pixel opening of the two adjacent pixel openings; or
in the first direction or the second direction, for two adjacent pixel openings that are each having a chamfered portion and corresponding to sub-pixels emitting light of a same color of all the sub-pixels, a chamfered portion included in each of the two adjacent pixel openings is located at a same corner position of a respective pixel opening of the two adjacent pixel openings; the two adjacent pixel openings have a same shape and a same size.

9. (canceled)

10. The display panel according to claim 1, wherein
the first sub-pixel, the second sub-pixel and the third sub-pixel in the pixel all extend in a fourth direction, and the fourth direction and the third direction form an included angle in a range of 80° to 100°, inclusive.

11. The display panel according to claim 4,
the first pixel opening adjacent to the first spacer is a pixel opening having a chamfered portion, and an orthographic projection of the first spacer on the pixel definition layer and the first pixel opening having the chamfered portion each have a side, and two sides are close to each other and substantially parallel to each other; and/or
the first pixel opening adjacent to the first spacer is a pixel opening having a chamfered portion, and the chamfered portion of the first pixel opening is substantially parallel to the first direction.

12. The display panel according to claim 4, wherein
the second pixel opening adjacent to the first spacer is a pixel opening having a chamfered portion; an orthographic projection of the first spacer on the pixel definition layer and the second pixel opening having the chamfered portion each have a side, and two sides are close to each other and substantially parallel to each other; and/or,
the second pixel opening adjacent to the first spacer is a pixel opening having a chamfered portion, and the chamfered portion of the second pixel opening is substantially parallel to the first direction.

13. The display panel according to claim 4, wherein
the third pixel opening adjacent to the first spacer is a pixel opening having a chamfered portion; an orthographic projection of the first spacer on the pixel definition layer and the third pixel opening having the chamfered portion each have a side, and the two sides are close to each other and substantially parallel to each other; and/or
the third pixel opening adjacent to the first spacer is a pixel opening having a chamfered portion, and the chamfered portion of the third pixel opening is substantially parallel to the second direction.

14. (canceled)

15. The display panel according to claim 1, wherein
the plurality of pixel openings are divided into a plurality of opening groups arranged in a fourth direction; the fourth direction intersects with the third direction; and
the plurality of spacers include at least one second spacer; a second spacer is in a shape of a strip and extends in the third direction between two adjacent opening groups of the plurality of opening groups.

16. The display panel according to claim 15, wherein
the two adjacent opening groups include a first opening group and a second opening group, and a length of the first opening group in the third direction is greater than a length of the second opening group in the third direction; and
a length of the second spacer in the third direction is less than or equal to the length of the first opening group in the third direction and is greater than or equal to the length of the second opening group in the third direction.

17. (canceled)

18. The display panel according to claim 2, wherein
the display panel comprises a display area having a contour, the plurality of spacers being located in the display area; wherein
the plurality of spacers include a plurality of third spacers; a third spacer of the plurality of third spacers is located between two adjacent pixel openings that are proximate to the contour of the plurality of pixel openings.

19. The display panel according to claim 18, wherein
an orthographic projection of the third spacer on the pixel definition layer has a side that is proximate to and substantially parallel to the contour; and/or
a pixel opening of the two adjacent pixel openings proximate to the contour and the orthographic projection of the third spacer on the pixel definition layer each have a side, and two sides are close to each other and parallel to each other.

20. (canceled)

21. (canceled)

22. The display panel according to claim 18, wherein
the plurality of pixel openings are divided into a plurality of opening groups arranged in a fourth direction; the fourth direction intersects with the third direction; and
the plurality of spacers further include at least one fourth spacer, wherein a fourth spacer of the at least one fourth spacer is located between an opening group of the plurality of opening groups that is located at outermost of the display panel and the contour.

23. The display panel according to claim 22, wherein
an orthographic projection of the fourth spacer on the pixel definition layer and the opening group located at the outermost of the display panel each have a side, and two sides are close to each other and substantially parallel to each other;
an orthographic projection of the fourth spacer on the pixel definition layer has a side that is proximate to and substantially parallel to the contour.

24. (canceled)

25. The display panel according to claim 3, wherein
the display panel comprises the first spacer and a third spacer, wherein shapes of an orthographic projection of the first spacer and an orthographic projection of the third spacer on the pixel definition layer are different or same, and/or orthographic projection of the first spacer and the orthographic projection of the third spacer on the pixel definition layer have a same size; and/or
the display panel comprises the first spacer and a fourth spacer, wherein the shapes of the orthographic projection of the first spacer and an orthographic projection of the fourth spacer on the pixel definition layer are different.

26. (canceled)

27. A display device, comprising:
the display panel according to claim 1.
